(19) United States
(12) Patent Application Publication
(10) Pub. No.: US 2025/0374761 A1
(43) Pub. Date: Dec. 4, 2025

(54) DISPLAY DEVICE

(71) Applicant: Samsung Display Co., LTD., Yongin-si (KR)

(72) Inventors: Cheon Myeong LEE, Yongin-si (KR); Yong Kyu KANG, Yongin-si (KR); Sang Ho KIM, Yongin-si (KR); Soon Gi PARK, Yongin-si (KR); Soo Min BAEK, Yongin-si (KR); Ji Won LEE, Yongin-si (KR); Ju Hwa HA, Yongin-si (KR)

(21) Appl. No.: 19/080,168

(22) Filed: Mar. 14, 2025

(30) Foreign Application Priority Data
May 28, 2024 (KR) 10-2024-0069372

(51) Int. Cl. H10K 59/121; G02B 27/01; H10H 29/32; H10H 29/49; H10K 59/131; H10K 102/00

(52) U.S. Cl. CPC H10K 59/1213; H10H 29/32; H10H 29/49; H10K 59/131; G02B 27/0172; H10K 2102/3035

(57) ABSTRACT

The present disclosure relates to a display device, and more particularly, to a display device capable of reducing or minimizing loss of image data information in merged pixels. A display device includes: a light-emitting element; a first switching transistor connected to a scan line and a first data line; a driving transistor connected to the first switching transistor, a driving voltage line, and the light-emitting element; a capacitor, one electrode of the capacitor being connected to a source electrode of the driving transistor; a second switching transistor connected to the scan line and a second data line; and a voltage divider connected to an other electrode of the capacitor, the first switching transistor, and the second switching transistor.

### CROSS-REFERENCE TO RELATED APPLICATION

This application claims priority to and the benefit of Korean Patent Application No. 10-2024-0069372, filed on May 28, 2024, in the Korean Intellectual Property Office, the entire disclosure of which is incorporated by reference herein.

### BACKGROUND

### 1. Field

The present disclosure relates to a display device, and more particularly, to a display device capable of reducing or minimizing loss of image data information in merged pixels.

### 2. Description of the Related Art

A head mounted display (HMD) is an image display device that is worn on a user's head in the form of glasses or helmets to form a focus at a close distance in front of the user's eyes. The head mounted display may implement virtual reality (VR) and/or augmented reality (AR).

The head mounted display magnifies an image displayed on a small display device by using a plurality of lenses, and displays the magnified image. Therefore, the display device applied to the head mounted display needs to provide high-resolution images, for example, images with a resolution of 3000 PPI (Pixels Per Inch) or higher. To this end, an organic light-emitting diode on silicon (OLEDoS), which is a high-resolution small organic light-emitting display device, is used as the display device applied to the head mounted display. The OLEDoS is an image display device in which an organic light-emitting diode (OLED) is disposed on a semiconductor wafer substrate on which a complementary metal oxide semiconductor (CMOS) is disposed.

### SUMMARY

Aspects and features of embodiments of the present disclosure provide a display device capable of reducing or minimizing loss of image data information in merged pixels.

According to one or more embodiments of the present disclosure, there is provided a display device including: a light-emitting element; a first switching transistor connected to a scan line and a first data line; a driving transistor connected to the first switching transistor, a driving voltage line, and the light-emitting element; a capacitor, one electrode of the capacitor being connected to a source electrode of the driving transistor; a second switching transistor connected to the scan line and a second data line; and a voltage divider connected to an other electrode of the capacitor, the first switching transistor, and the second switching transistor.

In one or more embodiments, the voltage divider includes: a first resistor, one end of the first resistor being connected to a drain electrode of the first switching transistor; and a second resistor, one end of the second resistor being connected to an other end of the first resistor and the other electrode of the capacitor, and an other end of the second resistor being connected to a drain electrode of the second switching transistor.

In one or more embodiments, a gate electrode of the first switching transistor is connected to the scan line; a source electrode of the first switching transistor is connected to the first data line; and a drain electrode of the first switching transistor is connected to a gate electrode of the driving transistor and the voltage divider.

In one or more embodiments, a gate electrode of the driving transistor is connected to a drain electrode of the first switching transistor; the source electrode of the driving transistor is connected to the one electrode of the capacitor and the driving voltage line; and a drain electrode of the driving transistor is connected to an anode electrode of the light-emitting element.

In one or more embodiments, a gate electrode of the second switching transistor is connected to the scan line; a source electrode of the second switching transistor is connected to the second data line; and a drain electrode of the second switching transistor is connected to the voltage divider.

In one or more embodiments, the light-emitting element is at an edge of a display panel of the display device.

In one or more embodiments, a display device includes: a light-emitting element; a first switching transistor connected to a first scan line and a data line; a first driving transistor connected to the first switching transistor, a driving voltage line, and a common voltage line; a first capacitor, one electrode of the first capacitor being connected to a source electrode of the first driving transistor; a second switching transistor connected to a second scan line and the data line; a second driving transistor connected to the second switching transistor, the driving voltage line, and the light-emitting element; a second capacitor, one electrode of the second capacitor being connected to a source electrode of the second driving transistor; and a voltage divider connected to an other electrode of the second capacitor, the second scan line, the first switching transistor, and the second switching transistor.

In one or more embodiments, the voltage divider includes: a first resistor, one end of the first resistor being connected to a drain electrode of the second switching transistor; a second resistor, one end of the second resistor being connected to an other end of the first resistor and the other electrode of the second capacitor; and a transistor connected to the second scan line, a drain electrode of the first switching transistor, and an other end of the second resistor.

In one or more embodiments, a gate electrode of the transistor is connected to the second scan line, wherein a source electrode of the transistor is connected to the drain electrode of the first switching transistor, and wherein a drain electrode of the transistor is connected to the other end of the second resistor.

In one or more embodiments, a gate electrode of the first switching transistor is connected to the first scan line, wherein a source electrode of the first switching transistor is connected to the data line, and wherein a drain electrode of the first switching transistor is connected to a gate electrode of the first driving transistor, an other electrode of the first capacitor, and the voltage divider.

In one or more embodiments, a gate electrode of the first driving transistor is connected to a drain electrode of the first switching transistor, wherein the source electrode of the first driving transistor is connected to the one electrode of the first capacitor and the driving voltage line, and wherein a drain electrode of the first driving transistor is connected to the common voltage line.

In one or more embodiments, a gate electrode of the second switching transistor is connected to the second scan line, wherein a source electrode of the second switching transistor is connected to the data line, and wherein a drain electrode of the second switching transistor is connected to a gate electrode of the second driving transistor and the voltage divider.

In one or more embodiments, a gate electrode of the second driving transistor is connected to a drain electrode of the second switching transistor, wherein the source electrode of the second driving transistor is connected to the one electrode of the second capacitor and the driving voltage line, and wherein a drain electrode of the second driving transistor is connected to the light-emitting element.

In one or more embodiments, the light-emitting element is at an edge of a display panel of the display device.

In one or more embodiments, a display device includes: a light-emitting element; a first switching transistor connected to a first scan line and a first data line; a first driving transistor connected to the first switching transistor, a driving voltage line, and a common voltage line; a first capacitor, one electrode of the first capacitor being connected to a source electrode of the first driving transistor; a second switching transistor connected to the first scan line and a second data line; a third switching transistor connected to a second scan line and the first data line; a second driving transistor connected to the third switching transistor, the driving voltage line, and the light-emitting element; a second capacitor, one electrode of the second capacitor being connected to a source electrode of the second driving transistor; a fourth switching transistor connected to the second scan line and the second data line; a first voltage divider connected to an other electrode of the first capacitor, the first switching transistor, and the second switching transistor; and a second voltage divider connected to an other electrode of the second capacitor, the second scan line, the first switching transistor, the third switching transistor, and the fourth switching transistor.

In one or more embodiments, the first voltage divider includes: first resistor, one end of the first resistor being connected to a drain electrode of the first switching transistor; and a second resistor, one end of the second resistor being connected to an other end of the first resistor and the other electrode of the first capacitor, and an other end of the second resistor being connected to a drain electrode of the second switching transistor.

In one or more embodiments, a gate electrode of the first switching transistor is connected to the first scan line, wherein a source electrode of the first switching transistor is connected to the first data line, and wherein a drain electrode of the first switching transistor is connected to a gate electrode of the first driving transistor, the first voltage divider, and the second voltage divider.

In one or more embodiments, a gate electrode of the first driving transistor is connected to a drain electrode of the first switching transistor, wherein the source electrode of the first driving transistor is connected to the one electrode of the first capacitor and the driving voltage line, and wherein a drain electrode of the first driving transistor is connected to the common voltage line.

In one or more embodiments, a gate electrode of the second switching transistor is connected to the first scan line, wherein a source electrode of the second switching transistor is connected to the second data line, and wherein a drain electrode of the second switching transistor is connected to the first voltage divider.

In one or more embodiments, the second voltage divider includes: a third resistor, one end of the third resistor being connected to a drain electrode of the third switching transistor; a fourth resistor, one end of the fourth resistor being connected to an other end of the third resistor and the other electrode of the second capacitor, and the other end of the fourth resistor being connected to a drain electrode of the fourth switching transistor; and a transistor connected to the one end of the fourth resistor, the second scan line, and a drain electrode of the first switching transistor.

In one or more embodiments, a gate electrode of the transistor is connected to the second scan line, wherein a source electrode of the transistor is connected to the drain electrode of the first switching transistor, and wherein a drain electrode of the transistor is connected to the one end of the fourth resistor.

In one or more embodiments, a gate electrode of the third switching transistor is connected to the second scan line, wherein a source electrode of the third switching transistor is connected to the first data line, and wherein a drain electrode of the third switching transistor is connected to a gate electrode of the second driving transistor and the second voltage divider.

In one or more embodiments, a gate electrode of the second driving transistor is connected to a drain electrode of the third switching transistor, wherein the source electrode of the second driving transistor is connected to the one electrode of the second capacitor and the driving voltage line, and wherein a drain electrode of the second driving transistor is connected to the light-emitting element.

In one or more embodiments, a gate electrode of the fourth switching transistor is connected to the second scan line, wherein a source electrode of the fourth switching transistor is connected to the second data line, and wherein a drain electrode of the second switching transistor is connected to the second voltage divider.

In one or more embodiments, the light-emitting element is at an edge of a display panel of the display device.

In accordance with the display device of one or more embodiments, loss of image data information in merged pixels may be reduced or minimized. Accordingly, image quality can be improved.

The effects of the present disclosure are not limited to the above-described effects and other effects which are not described herein will become apparent to those skilled in the art from the following description.

### BRIEF DESCRIPTION OF THE DRAWINGS

The above and other aspects and features of embodiments of the present disclosure will become more apparent by describing in detail example embodiments thereof with reference to the attached drawings, in which:

FIG. 1 is an exploded perspective view showing a display device according to one or more embodiments;

FIG. 2 is a block diagram illustrating a display device according to one or more embodiments;

FIG. 3 is an equivalent circuit diagram of a first pixel according to one or more embodiments;

FIG. 4 is a layout diagram illustrating an example of a display panel according to one or more embodiments;

FIGS. 5 and 6 are layout diagrams illustrating examples of the display area of FIG. 4;

FIG. 7 is a cross-sectional view illustrating an example of a display panel taken along the line I1-I1′ of FIG. 5;

FIG. 8 is an equivalent circuit diagram illustrating a first pixel according to one or more embodiments;

FIG. 9 is an equivalent circuit diagram of a plurality of pixels and a voltage divider of the display device according to one or more embodiments;

FIG. 10 is a diagram illustrating one or more embodiments of merging of pixels of FIG. 9;

FIG. 11 is an equivalent circuit diagram of a plurality of pixels and a voltage divider of the display device according to one or more embodiments;

FIG. 12 is a diagram illustrating one or more embodiments of merging of pixels of FIG. 11;

FIG. 13 is an equivalent circuit diagram of a plurality of pixels and a voltage divider of the display device according to one or more embodiments;

FIG. 14 is a diagram illustrating one or more embodiments of merging of pixels of FIG. 13;

FIG. 15 is a diagram illustrating a pixel density for each area of the display device according to one or more embodiments;

FIG. 16 is a perspective view illustrating a head mounted display according to one or more embodiments;

FIG. 17 is an exploded perspective view illustrating an example of the head mounted display of FIG. 16; and

FIG. 18 is a perspective view illustrating a head mounted display according to one or more embodiments.

FIG. 19 is a block diagram of an electronic device according to one embodiment.

FIGS. 20, 21 and 22 are schematic diagrams of electronic devices according to various embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Features of various embodiments of the present disclosure may be combined partially or totally. As will be clearly appreciated by those skilled in the art, technically various interactions and operations are possible. Various embodiments can be practiced individually or in combination.

Hereinafter, specific example embodiments will be described with reference to the accompanying drawings.

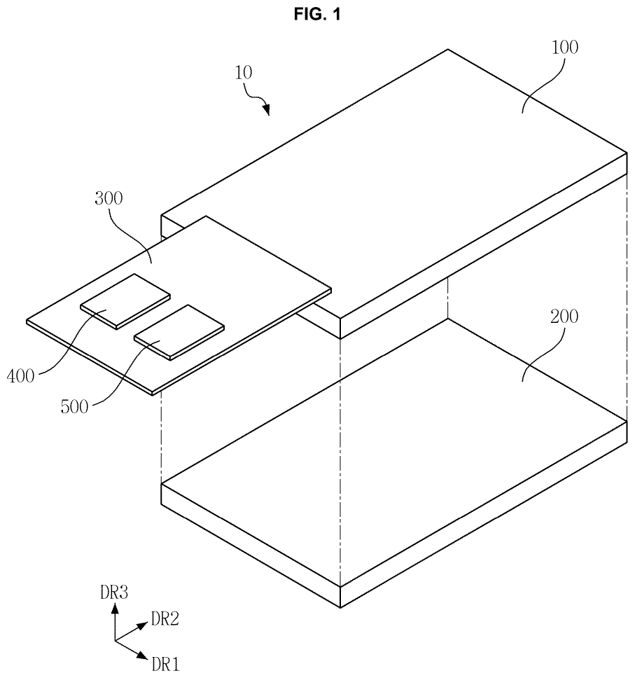

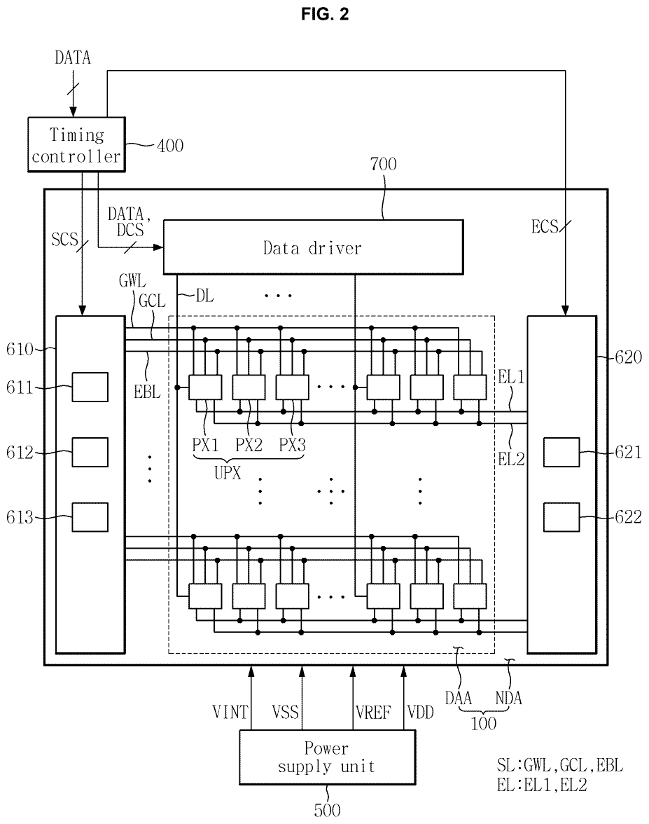

FIG. 1 is an exploded perspective view showing a display device according to one or more embodiments. FIG. 2 is a block diagram illustrating a display device according to one or more embodiments.

Referring to FIGS. 1 and 2, a display device 10 according to one or more embodiments is a device for displaying a moving image and/or a still image. The display device 10 according to one or more embodiments may be applied to portable electronic devices such as a mobile phone, a smartphone, a tablet personal computer, a mobile communication terminal, an electronic organizer, an electronic book, a portable multimedia player (PMP), a navigation system, an ultra-mobile PC (UMPC), and/or the like. For example, the display device 10 according to one or more embodiments may be applied as a display unit of a television, a laptop, a monitor, a billboard, and/or an Internet-of-Things (IoT) terminal. Alternatively, the display device 10 according to one or more embodiments may be applied to a smart watch, a watch phone, a head mounted display (HMD) for implementing virtual reality and augmented reality, and/or the like.

The display device 10 according to one or more embodiments includes a display panel 100, a heat dissipation layer 200, a circuit board 300, a timing control circuit 400, and a power supply circuit (i.e., a power supply unit) 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a suitable curvature (e.g., a predetermined curvature). The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the present disclosure is not limited thereto.

The display panel 100 includes a display area DAA for displaying an image and a non-display area NDA that does not display an image as shown in FIG. 2.

The display area DAA includes a plurality of pixels PX, a plurality of scan lines SL, a plurality of emission control lines EL, and a plurality of data lines DL.

The plurality of pixels PX may be arranged in a matrix form along the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1, while being arranged along the second direction DR2. The plurality of data lines DL may extend in the second direction DR2, while being arranged along the first direction DR1.

The plurality of scan lines SL include a plurality of write scan lines GWL, a plurality of control scan lines GCL, and a plurality of bias scan lines EBL. The plurality of emission control lines EL include a plurality of first emission control lines EL1 and a plurality of second emission control lines EL2.

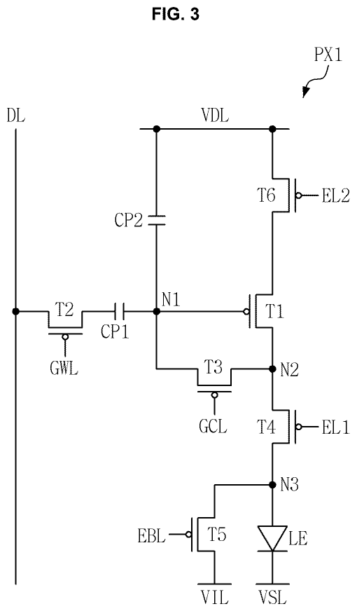

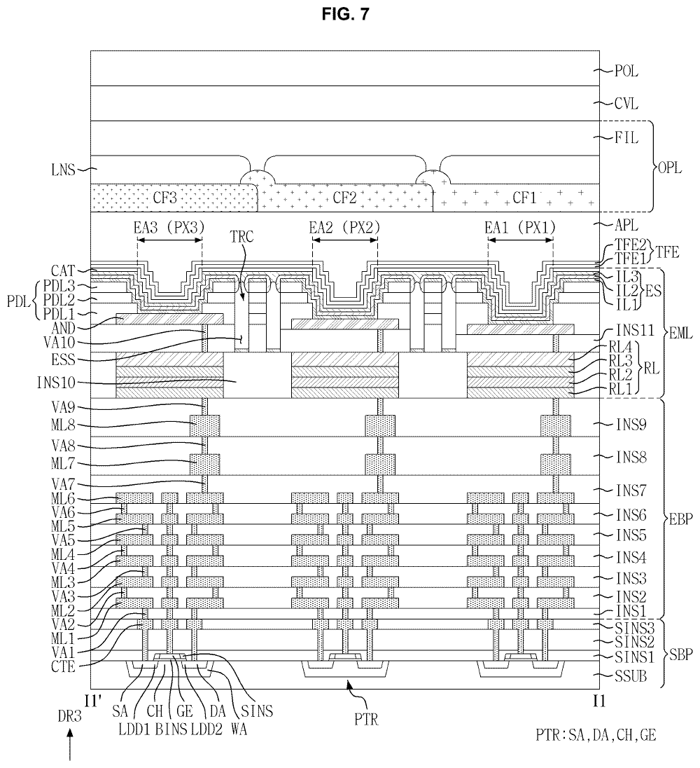

Each of a plurality of unit pixels UPX includes a plurality of pixels PX1, PX2, and PX3. The plurality of pixels PX1, PX2, and PX3 may include a plurality of pixel transistors as shown in FIG. 3, and the plurality of pixel transistors are formed through a semiconductor process and may be disposed on a semiconductor substrate SSUB (see FIG. 7). For example, the plurality of pixel transistors of a data driver 700 may be formed of complementary metal oxide semiconductor (CMOS).

Each of the plurality of pixels PX1, PX2, and PX3 may be connected to one of the plurality of write scan lines GWL, one of the plurality of control scan lines GCL, one of the plurality of bias scan lines EBL, one of the plurality of first emission control lines EL1, one of the plurality of second emission control lines EL2, and one of the plurality of data lines DL. Each of the plurality of pixels PX1, PX2, and PX3 may receive a data voltage of the data line DL in response to a write scan signal of the write scan line GWL, and emit light from the light-emitting element according to the data voltage.

The non-display area NDA includes a scan driver 610, an emission driver 620, and the data driver 700.

The scan driver 610 includes a plurality of scan transistors, and the emission driver 620 includes a plurality of light-emitting transistors. The plurality of scan transistors and the plurality of light-emitting transistors may be formed on the semiconductor substrate SSUB (see FIG. 7) through a semiconductor process. For example, the plurality of scan transistors and the plurality of light-emitting transistors may be formed of CMOS. Although it is illustrated in FIG. 2 that the scan driver 610 is disposed on the left side of the display area DAA and the emission driver 620 is disposed on the right side of the display area DAA, the present disclosure is not limited thereto. For example, the scan driver 610 and the emission driver 620 may be disposed on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines EBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed on the semiconductor substrate SSUB (see FIG. 7) through a semiconductor process. For example, the plurality of data transistors may be formed of CMOS.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the pixels PX1, PX2, and PX3 are selected by the write scan signal of the scan driver 610, and data voltages may be supplied to the selected pixels PX1, PX2, and PX3.

The heat dissipation layer 200 may overlap the display panel 100 in a third direction DR3, which is the thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer such as graphite, silver (Ag), copper (Cu), and/or aluminum (Al) having high thermal conductivity.

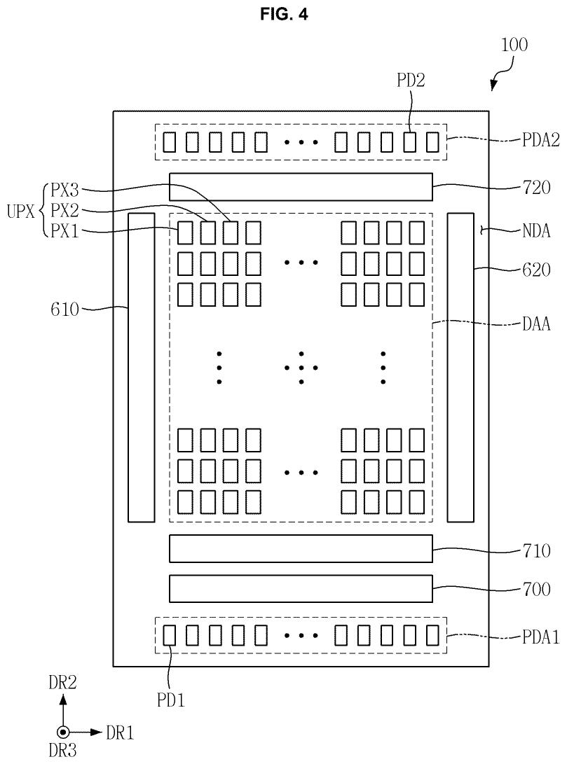

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board (FPCB) with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. One end of the circuit board 300 may be an opposite end of the other end of the circuit board 300 connected to the plurality of first pads PD1 (see FIG. 4) of the first pad portion PDA1 (see FIG. 4) of the display panel 100 by using a conductive adhesive member.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate reference voltage VREF, a common voltage VSS, a driving voltage VDD, and an initialization voltage VINT and supply them to the display panel 100. The common voltage VSS, the driving voltage VDD, and the initialization voltage VINT will be described later in conjunction with FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. In addition, the common voltage VSS, the driving voltage VDD, and the initialization voltage VINT of the power supply circuit 500 may be supplied to the display panel 100 through the circuit board 300.

Alternatively, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may be formed of CMOS. Each of the timing control circuit 400 and the power supply circuit 500 may be disposed between the data driver 700 and the first pad portion PDA1 (see FIG. 4).

FIG. 3 is an equivalent circuit diagram of a first pixel according to one or more embodiments.

Referring to FIG. 3, a first pixel PX1 may be connected to the write scan line GWL, the control scan line GCL, the bias scan line EBL, the first emission control line EL1, the second emission control line EL2, and the data line DL. In addition, the first pixel PX1 may be connected to a common voltage line VSL to which the common voltage VSS corresponding to a low potential voltage is applied, a driving voltage line VDL to which the driving voltage VDD corresponding to a high potential voltage is applied, and an initialization voltage line VIL to which the initialization voltage VINT is applied. That is, the common voltage line VSL may be a low potential voltage line, the driving voltage line VDL may be a high potential voltage line, and the initialization voltage line VIL may be an initialization voltage line. In this case, the common voltage VSS may be lower than the initialization voltage VINT. The driving voltage VDD may be higher than the initialization voltage VINT.

The first pixel PX1 includes a plurality of transistors T1 to T6, a light-emitting element LE, a first capacitor CP1, and a second capacitor CP2.

The light-emitting element LE emits light in response to a driving current flowing through the channel of a first transistor T1. The emission amount of the light-emitting element LE may be proportional to the driving current. The light-emitting element LE may be disposed between a fourth transistor T4 (or a third node N3) and the common voltage line VSL. The first electrode of the light-emitting element LE may be connected to the drain electrode of the fourth transistor T4, and the second electrode thereof may be connected to the common voltage line VSL. The first electrode of the light-emitting element LE may be an anode electrode, and the second electrode of the light-emitting element LE may be a cathode electrode. The light-emitting element LE may be an organic light-emitting diode (OLED) including a first electrode, a second electrode, and an organic light-emitting layer disposed between the first electrode and the second electrode, but the present disclosure is not limited thereto. For example, the light-emitting element LE may be an inorganic light-emitting element including a first electrode, a second electrode, and an inorganic semiconductor disposed between the first electrode and the second electrode, in which case the light-emitting element LE may be a micro light-emitting diode.

The first transistor T1 may be a driving transistor that controls a source-drain current (hereinafter referred to as “driving current”) flowing between the source electrode and the drain electrode thereof according to a voltage applied to the gate electrode thereof. The first transistor T1 includes a gate electrode connected to a first node N1, a source electrode connected to the drain electrode of a sixth transistor T6, and a drain electrode connected to a second node N2.

A second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 includes a gate electrode connected to the write scan line GWL, a source electrode connected to the data line DL, and a drain electrode connected to the one electrode of the first capacitor CP1.

A third transistor T3 may be disposed between the first node N1 and the second node N2. The third transistor T3 is turned on by the write control signal of the write control line GCL to connect the first node N1 to the second node N2. For this reason, because the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 includes a gate electrode connected to the first emission control line EL1, a source electrode connected to the second node N2, and a drain electrode connected to the third node N3.

The fifth transistor T5 may be disposed between the third node N3 and the initialization voltage line VIL. The fifth transistor T5 is turned on by the bias scan signal of the bias scan line EBL to connect the third node N3 to the initialization voltage line VIL. Accordingly, the initialization voltage VINT of the initialization voltage line VIL may be applied to the first electrode of the light-emitting element LE. The fifth transistor T5 includes a gate electrode connected to the bias scan line EBL, a source electrode connected to the third node N3, and a drain electrode connected to the initialization voltage line VIL.

The sixth transistor T6 may be disposed between the source electrode of the first transistor T1 and the driving voltage line VDL. The sixth transistor T6 is turned on by the second emission control signal of the second emission control line EL2 to connect the source electrode of the first transistor T1 to the driving voltage line VDL. Accordingly, the driving voltage VDD of the driving voltage line VDL may be applied to the source electrode of the first transistor T1. The sixth transistor T6 includes a gate electrode connected to the second emission control line EL2, a source electrode connected to the driving voltage line VDL, and a drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 (or the first node N1) and the driving voltage line VDL. The second capacitor CP2 includes one electrode connected to the gate electrode of the first transistor T1 (or the first node N1) and the other electrode connected to the driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the present disclosure is not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 3 that the first pixel PX1 includes the six transistors T1 to T6 and the two capacitors CP1 and CP2, the equivalent circuit diagram of the first pixel PX1 is not limited to the example shown in FIG. 3. For example, the number of the transistors and the number of the capacitors of the first pixel PX1 are not limited to the example shown in FIG. 3.

In addition, the equivalent circuit diagram of a second pixel PX2 and the equivalent circuit diagram of a third pixel PX3 may be substantially the same as the equivalent circuit diagram of the first pixel PX1 described in conjunction with FIG. 3. Thus, in the present disclosure, description of the equivalent circuit diagram of the second pixel PX2 and the equivalent circuit diagram of the third pixel PX3 will be omitted.

FIG. 4 is a layout diagram illustrating an example of a display panel according to one or more embodiments.

Referring to FIG. 4, the display area DAA of the display panel 100 according to one or more embodiments includes the plurality of pixels PX arranged in a matrix form. The non-display area NDA of the display panel 100 according to one or more embodiments includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. That is, the scan driver 610 may be disposed on the left side of the display area DAA, and the emission driver 620 may be disposed on the right side of the display area DAA. However, the present disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2.

The first pad portion PDA1 may be disposed outside the data driver 700 in the second direction DR2. That is, the first pad portion PDA1 may be disposed closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board (PCB) made of a rigid material or a flexible printed circuit board (FPCB) made of a flexible material.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2. That is, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. That is, the second distribution circuit 720 may be disposed on the upper side of the display area DAA.

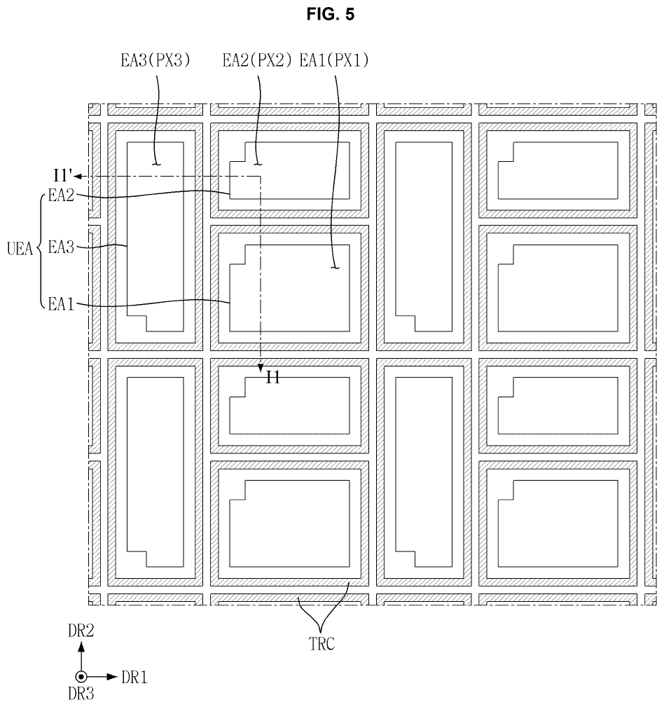

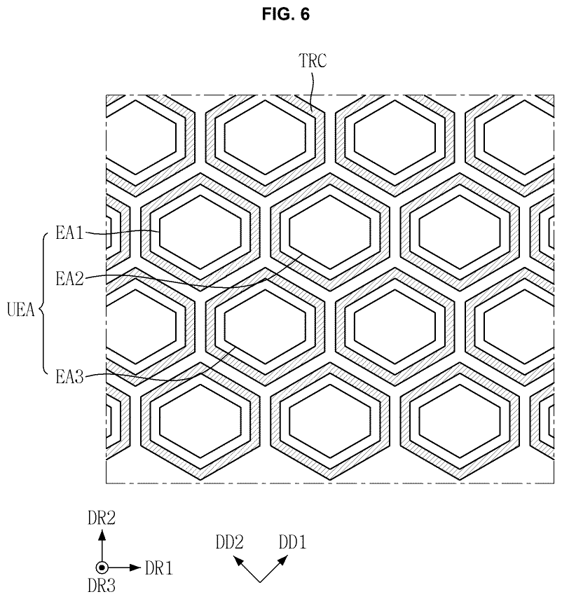

FIGS. 5 and 6 are layout diagrams illustrating examples of the display area of FIG. 4.

Referring to FIGS. 5 and 6, each of the plurality of unit pixels UPX includes a first emission area EA1 as an emission area of the first pixel PX1, a second emission area EA2 as an emission area of the second pixel PX2, and a third emission area EA3 as an emission area of the third pixel PX3. In other words, the unit pixel UPX may include a unit emission area UEA, and the unit emission area UEA includes the first emission area EA1, the second emission area EA2, and the third emission area EA3 described above.

Referring to FIGS. 5 and 6, each of the plurality of pixels PX includes the first emission area EA1 as an emission area of the first pixel PX1, the second emission area EA2 as an emission area of the second pixel PX2, and the third emission area EA3 as an emission area of the third pixel PX3.

Each of the first emission area EA1, the second emission area EA2, and the third emission area EA3 may have a polygonal, circular, elliptical, or atypical shape in a plan view.

The maximum length of the third emission area EA3 in the first direction DR1 may be less than the maximum length of the second emission area EA2 in the first direction DR1 and the maximum length of the first emission area EA1 in the first direction DR1. The maximum length of the second emission area EA2 in the first direction DR1 and the maximum length of the first emission area EA1 in the first direction DR1 may be substantially the same.

The maximum length of the third emission area EA3 in the second direction DR2 may be greater than the maximum length of the second emission area EA2 in the second direction DR2 and the maximum length of the first emission area EA1 in the second direction DR2. The maximum length of the second emission area EA2 in the second direction DR2 may be less than the maximum length of the first emission area EA1 in the second direction DR2. The maximum length of the third emission area EA3 in the second direction DR2 may be greater than the maximum length of the second emission area EA2 in the second direction DR2.

The first emission area EA1, the second emission area EA2, and the third emission area EA3 may have, in a plan view, a hexagonal shape formed of six straight lines as shown in FIGS. 5 and 6, but the present disclosure is not limited thereto. The first emission area EA1, the second emission area EA2, and the third emission area EA3 may have a polygonal shape other than a hexagon, a circular shape, an elliptical shape, or an atypical shape in a plan view.

As shown in FIG. 5, in each of the plurality of pixels PX, the third emission area EA3 and the second emission area EA2 may be adjacent to each other in the first direction DR1. Further, the first emission area EA1 and the third emission area EA3 may be adjacent to each other in the first direction DR1. In addition, the second emission area EA2 and the first emission area EA1 may be adjacent to each other in the second direction DR2. The area of the first emission area EA1, the area of the second emission area EA2, and the area of the third emission area EA3 may be different.

Alternatively, as shown in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

It is exemplified in FIGS. 5 and 6 that each of the plurality of pixels PX includes three emission areas EA1, EA2, and EA3, but the present disclosure is not limited thereto. That is, each of the plurality of pixels PX may include four emission areas.

In addition, the layout of the emission areas of the plurality of pixels PX is not limited to those illustrated in FIGS. 5 and 6. For example, the emission areas of the plurality of pixels PX may be disposed in a stripe structure in which the emission areas are arranged along the first direction DR1, a PENTILE® structure in which the emission areas are arranged in a diamond shape, or a hexagonal structure in which the emission areas having, in a plan view, a hexagonal shape are arranged as shown in FIG. 6. PENTILE® is a registered trademark of Samsung Display Co., Ltd., Republic of Korea.

FIG. 7 is a cross-sectional view illustrating an example of a display panel taken along the line I1-I1′ of FIG. 5.

Referring to FIG. 7, the display panel 100 includes a semiconductor backplane SBP, a light-emitting element backplane EBP, a display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, and/or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be reduced or prevented.

A first semiconductor insulating film SINS1 may be disposed on the semiconductor substrate SSUB and the gate electrode GE of the pixel transistor PTR. The first semiconductor insulating film SINS1 may be formed of silicon carbonitride (SiCN) and/or a silicon oxide (SiOx)-based inorganic film, but the present disclosure is not limited thereto.

A second semiconductor insulating film SINS2 may be disposed on the first semiconductor insulating film SINS1. The second semiconductor insulating film SINS2 may be formed of a silicon oxide (SiOx)-based inorganic film, but the present disclosure is not limited thereto.

The plurality of contact terminals CTE may be disposed on the second semiconductor insulating film SINS2. Each of the plurality of contact terminals CTE may be connected to one of the gate electrode GE, the source region SA, and the drain region DA of each of the pixel transistors PTR through a hole penetrating the first semiconductor insulating film SINS1 and the second semiconductor insulating film INS2. The plurality of contact terminals CTE may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOx)-based inorganic film, but the present disclosure is not limited thereto.

The semiconductor substrate SSUB may be replaced with a glass substrate or a polymer resin substrate such as polyimide. In this case, thin film transistors may be disposed on the glass substrate and/or the polymer resin substrate. The glass substrate may be a rigid substrate that does not bend, and the polymer resin substrate may be a flexible substrate that can be bent and/or curved.

The light-emitting element backplane EBP includes a plurality of conductive layers ML1 to ML8, a plurality of vias VA1 to VA9, and a plurality of insulating films INS1 to INS9. In the light-emitting element backplane EBP, the plurality of insulating films INS1 to INS9 disposed between the first to eighth conductive layers ML1 to ML8.

The first to eighth conductive layers ML1 to ML8 serve to connect the plurality of contact terminals CTE exposed from the semiconductor backplane SBP to thereby implement the circuit of the first pixel PX1 shown in FIG. 3. For example, the first to sixth transistors T1 to T6 are merely formed in the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and the first electrode of the light-emitting element LE is also accomplished through the first to eighth conductive layers ML1 to ML8.

The first insulating film INS1 may be disposed on the semiconductor backplane SBP. Each of the first vias VA1 may penetrate the first insulating film INS1 and be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate the second insulating film INS2 and may be connected to the exposed first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate the third insulating film INS3 and may be connected to the exposed second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate the fourth insulating film INS4 and may be connected to the exposed third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate the fifth insulating film INS5 and may be connected to the exposed fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate the sixth insulating film INS6 and may be connected to the exposed fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate the seventh insulating film INS7 and may be connected to the exposed sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate the eighth insulating film INS8 and may be connected to the exposed seventh conductive layer ML7. Each of the eighth conductive layers ML8 may be disposed on the eighth insulating film INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. The first to eighth vias VA1 to VA8 may be made of substantially the same material. First to eighth insulating films INS1 to INS8 may be formed of a silicon oxide (SiOx)-based inorganic film, but the present disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

A ninth insulating film INS9 may be disposed on the eighth insulating film INS8 and the eighth conductive layer ML8. The ninth insulating film INS9 may be formed of a silicon oxide (SiOx)-based inorganic film, but the present disclosure is not limited thereto.

Each of the ninth vias VA9 may penetrate the ninth insulating film INS9 and may be connected to the exposed eighth conductive layer ML8. The ninth vias VA9 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. The thickness of the ninth via VA9 may be approximately 16500 Å.

The display element layer EML may be disposed on the light-emitting element backplane EBP. The display element layer EML may include light-emitting elements LE each including a reflective electrode layer RL, tenth and eleventh insulating films INS10 and INS11, a tenth via VA10, a first electrode AND, a light-emitting stack ES, and a second electrode CAT; a pixel defining film PDL; and a plurality of trenches TRC.

The reflective electrode layer RL may be disposed on the ninth insulating film INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 7.

Each of the first reflective electrodes RL1 may be disposed on the ninth insulating film INS9, and may be connected to the ninth via VA9. The first reflective electrodes RL1 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the first reflective electrodes RL1 may include titanium nitride (TiN).

Each of the second reflective electrodes RL2 may be disposed on the first reflective electrode RL1. The second reflective electrodes RL2 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the second reflective electrodes RL2 may include aluminum (Al).

Each of the third reflective electrodes RL3 may be disposed on the second reflective electrode RL2. The third reflective electrodes RL3 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the third reflective electrodes RL3 may include titanium nitride (TiN).

Each of the fourth reflective electrodes RL4 may be disposed on the third reflective electrode RL3. The fourth reflective electrodes RL4 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the fourth reflective electrodes RL4 may include titanium (Ti).

Because the second reflective electrode RL2 is an electrode that substantially reflects light from the light-emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be approximately 850 Å. However, in one or more embodiments, the thickness of the second reflective electrode RL2 may be substantially the same as the thickness of each of the first reflective electrode RL1, the third reflective electrode RL3, and the fourth reflective electrode RL4. In one or more embodiments, the thickness of the fourth reflective electrode RL4 may be greater than the thickness of each of the first reflective electrode RL1, the second reflective electrode RL2, and the third reflective electrode RL3.

The tenth insulating film INS10 may be disposed on the ninth insulating film INS9. The tenth insulating film INS10 may be disposed between the reflective electrode layers RL adjacent to each other in a horizontal direction (e.g., the first direction DR1 or the second direction DR2). The tenth insulating film INS10 may be disposed on the reflective electrode layer RL in the third pixel PX3. The tenth insulating film INS10 may be formed of a silicon oxide (SiOx)-based inorganic film, but the present disclosure is not limited thereto.

The eleventh insulating film INS11 may be disposed on the tenth insulating film INS10 and the reflective electrode layer RL. The eleventh insulating film INS11 may be formed of a silicon oxide (SiOx)-based inorganic film, but the present disclosure is not limited thereto. The tenth insulating film INS10 and the eleventh insulating film INS11 may be an optical auxiliary layer through which light reflected by the reflective electrode layer RL passes, from among light emitted from the light-emitting elements LE.

In order to match the resonance distance of the light emitted from the light-emitting elements LE in at least one of the first pixel PX1, the second pixel PX2, or the third pixel PX3, the tenth insulating film INS10 and the eleventh insulating film INS11 may not be disposed under the first electrode AND of the first pixel PX1. In one or more embodiments, the first electrode AND of the first pixel PX1 may be directly disposed on the reflective electrode layer RL. The eleventh insulating film INS11 may be disposed under the first electrode AND of the second pixel PX2. In one or more embodiments, the tenth insulating film INS10 and the eleventh insulating film INS11 may be disposed under the first electrode AND of the third pixel PX3. However, in one or more embodiments, in each of the first, second, and third pixels PX1, PX2, and PX3, the eleventh insulating film INS11 may be disposed under the first electrode AND, and the thickness in the third direction DR3 of the eleventh insulating film INS11 may be different in each of the first pixel PX1, the second pixel PX2, and the third pixel PX3.

In summary, the distance between the first electrode AND and the reflective electrode layer RL may be different in the first pixel PX1, the second pixel PX2, and the third pixel PX3. In order to adjust the distance from the reflective electrode layer RL to the second electrode CAT according to the main wavelength of the light emitted from each of the first pixel PX1, the second pixel PX2, and the third pixel PX3, the presence or absence of the tenth insulating film INS10 and the eleventh insulating film INS11 may be set in each of the first pixel PX1, the second pixel PX2, and the third pixel PX3. For example, it is illustrated in FIG. 7 that the distance between the first electrode AND and the reflective electrode layer RL in the third pixel PX3 is greater than the distance between the first electrode AND and the reflective electrode layer RL in the second pixel PX2 and the distance between the first electrode AND and the reflective electrode layer RL in the first pixel PX1, and the distance between the first electrode AND and the reflective electrode layer RL in the second pixel PX2 is greater than the distance between the first electrode AND and the reflective electrode layer RL in the first pixel PX1, but the present disclosure is not limited thereto.

In addition, although the tenth insulating film INS10 and the eleventh insulating film INS11 are illustrated in the present disclosure, a twelfth insulating film disposed under the first electrode AND of the first pixel PX1 may be added. In this case, the eleventh insulating film INS11 and a twelfth insulating film INS12 may be disposed under the first electrode AND of the second pixel PX2, and the tenth insulating film INS10, the eleventh insulating film INS11, and the twelfth insulating film INS12 may be disposed under the first electrode AND of the third pixel PX3.

Each of the tenth vias VA10 may penetrate the tenth insulating film INS10 and/or the eleventh insulating film INS11 in the first pixel PX1, the second pixel PX2 and the third pixel PX3 and may be connected to the exposed fourth reflective electrode RL4. The tenth vias VA10 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. The thickness of the tenth via VA10 in the second pixel PX2 may be less than the thickness of the tenth via VA10 in the third pixel PX3, and the thickness of the tenth via VA10 in the first pixel PX1 may be less than the thickness of the tenth via VA10 in the second pixel PX2.

The first electrode AND of each of the light-emitting elements LE may be disposed on the eleventh insulating film INS11 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the first electrode AND of each of the light-emitting elements LE may be titanium nitride (TiN).

The pixel defining film PDL may be disposed on a part of the first electrode AND of each of the light-emitting elements LE. The pixel defining film PDL may cover the edge of the first electrode AND of each of the light-emitting elements LE. The pixel defining film PDL may serve to partition the first emission areas EA1, the second emission areas EA2, and the third emission areas EA3.

The first emission area EA1 may be defined as an area in which the first electrode AND, the light-emitting stack ES, and the second electrode CAT are sequentially stacked in the first pixel PX1 to emit light. The second emission area EA2 may be defined as an area in which the first electrode AND, the light-emitting stack ES, and the second electrode CAT are sequentially stacked in the second pixel PX2 to emit light. The third emission area EA3 may be defined as an area in which the first electrode AND, the light-emitting stack ES, and the second electrode CAT are sequentially stacked in the third pixel PX3 to emit light.

The pixel defining film PDL may include first to third pixel defining films PDL1, PDL2, and PDL3. The first pixel defining film PDL1 may be disposed on the edge of the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOₓ)-based inorganic film, but the present disclosure is not limited thereto. The first pixel defining film PDL1, the second pixel defining film PDL2, and the third pixel defining film PDL3 may each have a thickness of about 500 Å.

When the first pixel defining film PDL1, the second pixel defining film PDL2, and the third pixel defining film PDL3 are formed as one pixel defining film, the height of the one pixel defining film increases, so that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. The width of the first pixel defining film PDL1 refers to the horizontal length of the first pixel defining film PDL1 defined in the first direction DR1 and the second direction DR2.

Each of the plurality of trenches TRC may penetrate the first pixel defining film PDL1, the second pixel defining film PDL2, and the third pixel defining film PDL3. Furthermore, each of the plurality of trenches TRC may penetrate the eleventh insulating film INS11. In one or more embodiments, the tenth insulating film INS10 may be partially recessed at each of the plurality of trenches TRC.

At least one trench TRC may be disposed between the neighboring pixels PX1, PX2, and PX3. Although FIG. 7 illustrates that two trenches TRC are disposed between adjacent pixels PX1, PX2, and PX3, the present disclosure is not limited thereto.

The light-emitting stack ES may include a plurality of stack layers. FIG. 7 illustrates that the light-emitting stack ES has a three-tandem structure including a first stack layer IL1, a second stack layer IL2, and a third stack layer IL3, but the present disclosure is not limited thereto. For example, the light-emitting stack ES may have a two-tandem structure including two intermediate layers.

In the three-tandem structure, the light-emitting stack ES may have a tandem structure including a plurality of stack layers IL1, IL2, and IL3 that emit different lights. For example, the light-emitting stack ES may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked.

The first stack layer IL1 may have a structure in which a first hole transport layer, a first organic light-emitting layer that emits light of the first color, and a first electron transport layer are sequentially stacked. The second stack layer IL2 may have a structure in which a second hole transport layer, a second organic light-emitting layer that emits light of the third color, and a second electron transport layer are sequentially stacked. The third stack layer IL3 may have a structure in which a third hole transport layer, a third organic light-emitting layer that emits light of the second color, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and may be disposed on the bottom surface of each trench TRC. Due to the trench TRC, the first stack layer IL1 may be cut off between the neighboring pixels PX1, PX2, and PX3. The second stack layer IL2 may be disposed on the first stack layer IL1. Due to the trench TRC, the second stack layer IL2 may be cut off between the neighboring pixels PX1, PX2, and PX3. A cavity ESS or an empty space may be disposed between the first stack layer IL1 and the second stack layer IL2. The third stack layer IL3 may be disposed on the second stack layer IL2. The third stack layer IL3 is not cut off by the trench TRC and may be disposed to cover the second stack layer IL2 in each of the trenches TRC. That is, in the three-tandem structure, each of the plurality of trenches TRC may be a structure for cutting off the first to second stack layers IL1 and IL2, the first charge generation layer, and the second charge generation layer of the display element layer EML between the pixels PX1, PX2, and PX3 adjacent to each other. In addition, in the two-tandem structure, each of the trenches TRC may be a structure for cutting off the charge generation layer disposed between a lower intermediate layer and an upper intermediate layer, and the lower intermediate layer.

In order to stably cut off the first and second stack layers IL1 and IL2 of the display element layer EML between adjacent pixels PX1, PX2, and PX3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the first to third stack layers IL1, IL2, and IL3 of the display element layer EML between the neighboring pixels PX1, PX2, and PX3, another structure may exist instead of the trench TRC. For example, instead of the trench TRC, a reverse tapered partition wall may be disposed on the pixel defining film PDL.

The number of the stack layers IL1, IL2, and IL3 that emit different lights is not limited to that shown in FIG. 7. For example, the light-emitting stack ES may include two intermediate layers. In this case, one of the two intermediate layers may be substantially the same as the first stack layer IL1, and the other may include a second hole transport layer, a second organic light-emitting layer, a third organic light-emitting layer, and a second electron transport layer. In this case, a charge generation layer for supplying electrons to one intermediate layer and supplying charges to the other intermediate layer may be disposed between the two intermediate layers.

In addition, FIG. 7 illustrates that the first to third stack layers IL1, IL2, and IL3 are all disposed in the first emission area EA1, the second emission area EA2, and the third emission area EA3, but the present disclosure is not limited thereto. For example, the first stack layer IL1 may be disposed in the first emission area EA1, and may be omitted from the second emission area EA2 and the third emission area EA3. Furthermore, the second stack layer IL2 may be disposed in the second emission area EA2 and may be omitted from the first emission area EA1 and the third emission area EA3. Further, the third stack layer IL3 may be disposed in the third emission area EA3 and may be omitted from the first emission area EA1 and the second emission area EA2. In this case, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC. The second electrode CAT may be formed of a transparent conductive material (TCO) such as ITO and/or IZO that can transmit light or a semi-transmissive conductive material such as magnesium (Mg), silver (Ag), and/or an alloy of Mg and Ag. When the second electrode CAT is formed of a semi-transmissive conductive material, the light emission efficiency may be improved in each of the first to third pixels PX1, PX2, and PX3 due to a micro-cavity effect.

The encapsulation layer TFE may be disposed on the display element layer EML. The encapsulation layer TFE may include at least one inorganic film TFE1 and TFE2 to reduce or prevent oxygen and/or moisture from permeating into the display element layer EML. For example, the encapsulation layer TFE may include the first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films selected from silicon nitride (SiNx), silicon oxy nitride (SiON), and/or silicon oxide (SiOx) are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed of titanium oxide (TiOx) and/or aluminum oxide (AlOx), but the present disclosure is not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

An organic film APL may be a layer for increasing the interfacial adhesion between the encapsulation layer TFE and the optical layer OPL. The organic film APL may be an organic film such as acrylic resin, epoxy resin, phenolic resin, polyamide resin, and/or polyimide resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the organic film APL.

The first color filter CF1 may overlap the first emission area EA1 of the first pixel PX1. The first color filter CF1 may transmit light of the first color, i.e., light of a blue wavelength band. The blue wavelength band may be about 370 nm to about 460 nm. Thus, the first color filter CF1 may transmit light of the first color from among light emitted from the first emission area EA1.

The second color filter CF2 may overlap the second emission area EA2 of the second pixel PX2. The second color filter CF2 may transmit light of the second color, i.e., light of a green wavelength band. The green wavelength band may be about 480 nm to about 560 nm. Thus, the second color filter CF2 may transmit light of the second color from among light emitted from the second emission area EA2.

The third color filter CF3 may overlap the third emission area EA3 of the third pixel PX3. The third color filter CF3 may transmit light of the third color, i.e., light of a red wavelength band. The red wavelength band may be about 600 nm to about 750 nm. Thus, the third color filter CF3 may transmit light of the third color from among light emitted from the third emission area EA3.

The plurality of lenses LNS may be disposed on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction (e.g., the third direction DR3).

The filling layer FIL may be disposed on the plurality of lenses LNS. The filling layer FIL may have a suitable refractive index (e.g., a predetermined refractive index) such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, and/or polyimide resin.

The cover layer CVL may be disposed on the filling layer FIL. The cover layer CVL may be a glass substrate and/or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be disposed on one surface of the cover layer CVL. The polarizing plate POL may be a structure for reducing or preventing visibility degradation caused by reflection of external light. The polarizing plate POL may include a linear polarizing plate and/or a phase retardation film. For example, the phase retardation film may be a λ/4 plate (e.g., a quarter-wave plate), but the present disclosure is not limited thereto. However, when visibility degradation caused by reflection of external light is sufficiently overcome by the first to third color filters CF1, CF2, and CF3, the polarizing plate POL may be omitted.

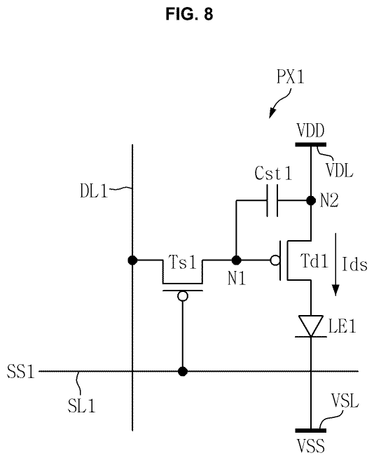

FIG. 8 is an equivalent circuit diagram illustrating the first pixel PX1 according to one or more embodiments.

Referring to FIG. 8, the first pixel PX1 may be connected to the scan line and the data line DL. Further, the first pixel PX1 may be connected to the common voltage line VSL to which the common voltage VSS corresponding to a low potential voltage is applied, and the driving voltage line VDL to which the driving voltage VDD corresponding to a high potential voltage is applied. For example, the common voltage line VSL may be a low potential voltage line and the driving voltage line VDL may be a high potential voltage line.

The first pixel PX1 may include a first switching transistor Ts1, a first driving transistor Td1, a first capacitor Cst1, and a first light-emitting element LE1.

The first light-emitting element LE1 emits light in response to a driving current Ids flowing through the channel of the first driving transistor Td1. The emission amount of the first light-emitting element LE1 may be proportional to the driving current Ids. The first light-emitting element LE1 may be connected between the drain electrode of the first driving transistor Td1 and the common voltage line VSL. The anode electrode of the first light-emitting element LE1 may be connected to the drain electrode of the first driving transistor Td1, and the cathode electrode thereof may be connected to the common voltage line VSL.

The first driving transistor Td1 may be a driving transistor that controls a drain-source current (Ids, hereinafter referred to as “driving current”) flowing between the source electrode and the drain electrode thereof according to a voltage applied to the gate electrode thereof. The first driving transistor Td1 may include a gate electrode connected to the first node N1, a source electrode connected to the driving voltage line VDL through a second node N2, and a drain electrode connected to the anode electrode of the first light-emitting element LE1.

The first switching transistor Ts1 may be connected between a first data line DL1 and the first node N1. The first switching transistor Ts1 may be turned on by a first scan signal SS1 of a first scan line SL1 to connect the first data line DL1 to the first node N1. The first switching transistor Ts1 may include a gate electrode connected to the first scan line SL1, a source electrode connected to the first data line DL1, and a drain electrode connected to the first node N1. The first capacitor Cst1 may be connected between the first node N1 and the second node N2.

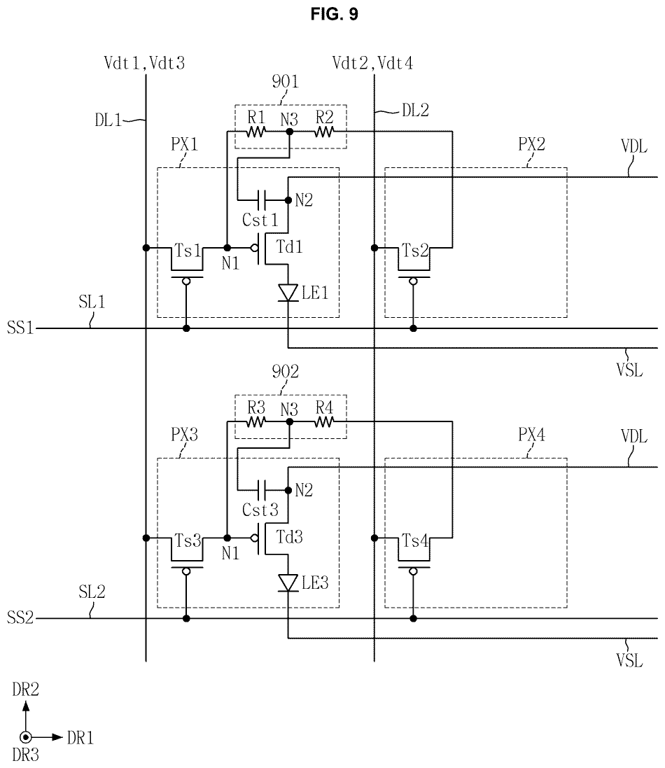

FIG. 9 is an equivalent circuit diagram of a plurality of pixels and a voltage divider of the display device 10 according to one or more embodiments.

As in the example shown in FIG. 9, the display device 10 according to one or more embodiments may include the first pixel PX1, the second pixel PX2, the third pixel PX3, a fourth pixel PX4, a first voltage divider 901, and a second voltage divider 902.

The first pixel PX1 and the second pixel PX2 may be disposed along the first direction DR1. For example, the first pixel PX1 and the second pixel PX2 may be disposed adjacent to each other in the first direction DR1 in a first row.

The third pixel PX3 and the fourth pixel PX4 may be disposed along the first direction DR1. For example, the third pixel PX3 and the fourth pixel PX4 may be disposed adjacent to each other in the first direction DR1 in a second row.

The first pixel PX1 and the third pixel PX3 may be disposed along the second direction DR2. For example, the first pixel PX1 and the third pixel PX3 may be disposed adjacent to each other in the second direction DR2 in a first column.

The second pixel PX2 and the fourth pixel PX4 may be disposed along the second direction DR2. For example, the second pixel PX2 and the fourth pixel PX4 may be disposed adjacent to each other in the second direction DR2 in a second column.

The first pixel PX1 and the second pixel PX2 may be commonly connected to the first scan line SL1, and may be connected to different data lines. For example, the first pixel PX1 may be connected to the first data line DL1, and the second pixel PX2 may be connected to a second data line DL2.

The third pixel PX3 and the fourth pixel PX4 may be commonly connected to a second scan line SL2, and may be connected to different data lines. For example, the third pixel PX3 may be connected to the first data line DL1, and the fourth pixel PX4 may be connected to the second data line DL2.

The first pixel PX1 and the third pixel PX3 may be commonly connected to the first data line DL1, and may be connected to different scan lines. For example, the first pixel PX1 may be connected to the first scan line SL1, and the third pixel PX3 may be connected to the second scan line SL2.

The second pixel PX2 and the fourth pixel PX4 may be commonly connected to the second data line DL2, and may be connected to different scan lines. For example, the second pixel PX2 may be connected to the first scan line SL1, and the fourth pixel PX4 may be connected to the second scan line SL2.

The first pixel PX1 may include the first switching transistor Ts1, the first driving transistor Td1, the first capacitor Cst1, and the first light-emitting element LE1.

The first switching transistor Ts1, the first driving transistor Td1, and the first light-emitting element LE1 that are provided in the first pixel PX1 of FIG. 9 may be the same as the first switching transistor Ts1, the first driving transistor Td1, and the first light-emitting element LE1 that are provided in the first pixel PX1 of FIG. 8 described above.

The first capacitor Cst1 of the first pixel PX1 may include a first electrode connected to the first voltage divider 901 and a second electrode connected to the second node N2 (e.g., the source electrode of the first driving transistor Td1) of the first pixel PX1. For example, the first electrode of the first capacitor Cst1 may be connected to the third node N3 (e.g., a junction between a first resistor R1 and a second resistor R2) of the first voltage divider 901.

The second pixel PX2 may include a second switching transistor Ts2. The second switching transistor Ts2 may include a gate electrode connected to the first scan line SL1, a source electrode connected to the second data line DL2, and a drain electrode connected to the first voltage divider 901. For example, the drain electrode of the second switching transistor Ts2 may be connected to the second resistor R2 of the first voltage divider 901.

The third pixel PX3 may include a third switching transistor Ts3, a third driving transistor Td3, a third capacitor Cst3, and a third light-emitting element LE3.

The third switching transistor Ts3 of the third pixel PX3 may include a gate electrode connected to the second scan line SL2, a source electrode connected to the first data line DL1, and a drain electrode connected to the first node N1 (e.g., the gate electrode of the third driving transistor Td3) of the third pixel PX3.

The third driving transistor Td3 of the third pixel PX3 may include a gate electrode connected to the first node N1 (e.g., the drain electrode of the third switching transistor Ts3) of the third pixel PX3, a source electrode connected to the driving voltage line VDL through the second node N2 of the third pixel PX3, and a drain electrode connected to the anode electrode of the third light-emitting element LE3.

The third capacitor Cst3 of the third pixel PX3 may include a first electrode connected to the second voltage divider 902 and a second electrode connected to the second node N2 (e.g., the source electrode of the third driving transistor Td3) of the third pixel PX3. For example, the first electrode of the third capacitor Cst3 may be connected to the third node N3 (e.g., a junction between a third resistor R3 and a fourth resistor R4) of the second voltage divider 902.

The third light-emitting element LE3 of the third pixel PX3 may include an anode electrode connected to the drain electrode of the third driving transistor Td3 and a cathode electrode connected to the common voltage line VSL.

The fourth pixel PX4 may include a fourth switching transistor Ts4. The fourth switching transistor Ts4 may include a gate electrode connected to the second scan line SL2, a source electrode connected to the second data line DL2, and a drain electrode connected to the second voltage divider 902. For example, the drain electrode of the fourth switching transistor Ts4 may be connected to the fourth resistor R4 of the second voltage divider 902.

The first voltage divider 901 may connect the first pixel PX1 and the second pixel PX2 adjacent in the first direction DR1 in the first row to each other. The first voltage divider 901 may generate a first intermediate data voltage based on a first data voltage Vdt1 applied to the first pixel PX1 and a second data voltage Vdt2 applied to the second pixel PX2. Here, the first data voltage Vdt1 applied to the first pixel PX1 may be, e.g., the first data voltage Vdt1 applied to the first node N1 of the first pixel PX1 through the turned-on first switching transistor Ts1. Further, the second data voltage Vdt2 applied to the second pixel PX2 may be, e.g., the second data voltage Vdt2 applied to the drain electrode of the second switching transistor Ts2 through the turned-on second switching transistor Ts2. A first average data voltage may include an average value (or a median value) for the first data voltage Vdt1 applied to the first pixel PX1 and the second data voltage Vdt2 applied to the second pixel PX2. For example, a value obtained by dividing the sum of the value of the first data voltage Vdt1 applied to the first pixel PX1 and the value of the second data voltage Vdt2 applied to the second pixel PX2 by 2 may be the value of the aforementioned first average data voltage.

The first voltage divider 901 may include at least one resistor. For example, the first voltage divider 901 may include the first resistor R1 and the second resistor R2 connected to each other through the third node N3 of the first voltage divider 901.

The first resistor R1 of the first voltage divider 901 may be connected between the first node N1 (e.g., the gate electrode of the first driving transistor Td1) of the first pixel PX1 and the third node N3 of the first voltage divider 901.

The second resistor R2 of the first voltage divider 901 may be connected between the third node N3 of the first voltage divider 901 and the drain electrode of the second switching transistor Ts2.

In one or more embodiments, the number of pixels connected to each other by the first voltage divider 901 may be two or more. For example, three or more pixels adjacent to each other in the first direction DR1 in the first row may be connected to each other by the first voltage divider 901.

The second voltage divider 902 may connect the third pixel PX3 and the fourth pixel PX4 adjacent in the first direction DR1 in the second row to each other. The second voltage divider 902 may generate a second intermediate data voltage based on a third data voltage Vdt3 applied to the third pixel PX3 and a fourth data voltage Vdt4 applied to the fourth pixel PX4. Here, the third data voltage Vdt3 applied to the third pixel PX3 may be, e.g., the third data voltage Vdt3 applied to the first node N1 of the third pixel PX3 through the turned-on third switching transistor Ts3. Further, the fourth data voltage Vdt4 applied to the fourth pixel PX4 may be, e.g., the fourth data voltage Vdt4 applied to the drain electrode of the fourth switching transistor Ts4 through the turned-on fourth switching transistor Ts4. A second average data voltage may include an average value (or a median value) for the third data voltage Vdt3 applied to the third pixel PX3 and the fourth data voltage Vdt4 applied to the fourth pixel PX4. For example, a value obtained by dividing the sum of the value of the third data voltage Vdt3 applied to the third pixel PX3 and the value of the fourth data voltage Vdt4 applied to the fourth pixel PX4 by 2 may be the value of the aforementioned second average data voltage.

The second voltage divider 902 may include at least one resistor. For example, the second voltage divider 902 may include the third resistor R3 and the fourth resistor R4 connected to each other through the third node N3 of the second voltage divider 902.

The third resistor R3 of the second voltage divider 902 may be connected between the first node N1 (e.g., the gate electrode of the third driving transistor Td3) of the third pixel PX3 and the third node N3 of the second voltage divider 902.

The fourth resistor R4 of the second voltage divider 902 may be connected between the third node N3 of the second voltage divider 902 and the drain electrode of the fourth switching transistor Ts4.

In one or more embodiments, the number of pixels connected to each other by the second voltage divider 902 may be two or more. For example, three or more pixels adjacent to each other in the first direction DR1 in the second row may be connected to each other by the second voltage divider 902.

The operation of the display device 10 of FIG. 9 configured as described above will be described below.

When the first scan signal SS1 is applied to the first scan line SL1, the first switching transistor Ts1 and the second switching transistor Ts2 connected to the first scan line SL1 through the gate electrode may each be turned on.

During a period in which the first scan signal SS1 is applied to the first scan line SL1, the first data voltage Vdt1 may be applied to the first data line DL1, and the second data voltage Vdt2 may be applied to the second data line DL2.

The first data voltage Vdt1 from the first data line DL1 may be applied to the first node N1 (e.g., the gate electrode of the first driving transistor Td1) of the first pixel PX1 through the turned-on first switching transistor Ts1. Further, the second data voltage Vdt2 from the second data line DL2 may be applied to the second pixel PX2 through the turned-on second switching transistor Ts2. For example, the second data voltage Vdt2 may be applied to the drain electrode of the turned-on second switching transistor Ts2.

The first data voltage Vdt1 applied to the first node N1 of the first pixel PX1 and the second data voltage Vdt2 applied to the drain electrode of the second switching transistor Ts2 of the second pixel PX2 may each be applied to the first voltage divider 901. For example, the first data voltage Vdt1 of the first pixel PX1 may be applied to the first resistor R1, and the second data voltage Vdt2 of the second pixel PX2 may be applied to the second resistor R2.

The first data voltage Vdt1 applied to the first pixel PX1 and the second data voltage Vdt2 applied to the second pixel PX2 may be divided according to the resistance ratio of the first resistor R1 and the second resistor R2 of the first voltage divider 901, and the divided voltage may be the aforementioned first average data voltage. The first average data voltage may be provided through the third node N3 of the first voltage divider 901. For example, the first average data voltage from the first voltage divider 901 may be applied to the first electrode of the first capacitor Cst1. The first average data voltage may be stored and maintained in the first capacitor Cst1.

Therefore, during the emission period of the first pixel PX1 and the second pixel PX2, the voltage of the gate electrode of the first driving transistor Td1 may be maintained at the first average data voltage corresponding to the average value of the first data voltage Vdt1 and the second data voltage Vdt2. Therefore, during the emission period of the first pixel PX1 and the second pixel PX2, the first driving transistor Td1 may conduct and supply a driving current according to the first average data voltage to the first light-emitting element LE1. During the emission period of the first pixel PX1 and the second pixel PX2, the first light-emitting element LE1 may provide light with a luminance of an average gray level corresponding to the average value of the gray level corresponding to the first data voltage Vdt1 and the gray level corresponding to the second data voltage Vdt2. Accordingly, the light of the first light-emitting element LE1 may include both information on the first data voltage Vdt1 and information on the second data voltage Vdt2. Accordingly, the loss of image data information in the merged pixels PX1 and PX2 may be reduced or minimized, thereby improving the image quality of the display device 10.

Thereafter, when the second scan signal SS2 is applied to the second scan line SL2, the third switching transistor Ts3 and the fourth switching transistor Ts4 connected to the second scan line SL2 through the gate electrode may each be turned on.

During the period in which the second scan signal SS2 is applied to the second scan line SL2, the third data voltage Vdt3 may be applied to the first data line DL1, and the fourth data voltage Vdt4 may be applied to the second data line DL2.

The third data voltage Vdt3 from the first data line DL1 may be applied to the first node N1 (e.g., the gate electrode of the third driving transistor Td3) of the third pixel PX3 through the turned-on third switching transistor Ts3. Further, the fourth data voltage Vdt4 from the second data line DL2 may be applied to the fourth pixel PX4 through the turned-on fourth switching transistor Ts4. For example, the fourth data voltage Vdt4 may be applied to the drain electrode of the turned-on fourth switching transistor Ts4.

The third data voltage Vdt3 applied to the first node N1 of the third pixel PX3 and the fourth data voltage Vdt4 applied to the drain electrode of the fourth switching transistor Ts4 of the fourth pixel PX4 may each be applied to the second voltage divider 902. For example, the third data voltage Vdt3 of the third pixel PX3 may be applied to the third resistor R3, and the fourth data voltage Vdt4 of the fourth pixel PX4 may be applied to the fourth resistor R4.

The third data voltage Vdt3 applied to the third pixel PX3 and the fourth data voltage Vdt4 applied to the fourth pixel PX4 may be divided according to the resistance ratio of the third resistor R3 and the fourth resistor R4 of the second voltage divider 902, and the divided voltage may be the aforementioned second average data voltage. The second average data voltage may be provided through the third node N3 of the second voltage divider 902. For example, the second average data voltage from the second voltage divider 902 may be applied to the first electrode of the third capacitor Cst3. The second average data voltage may be stored and maintained in the third capacitor Cst3.

Therefore, during the emission period of the third pixel PX3 and the fourth pixel PX4, the voltage of the gate electrode of the third driving transistor Td3 may be maintained at the second average data voltage corresponding to the average value of the third data voltage Vdt3 and the fourth data voltage Vdt4. Therefore, during the emission period of the third pixel PX3 and the fourth pixel PX4, the third driving transistor Td3 may conduct and supply a driving current according to the second average data voltage to the third light-emitting element LE3. During the emission period of the third pixel PX3 and the fourth pixel PX4, the third light-emitting element LE3 may provide light with a luminance of an average gray level corresponding to the gray level corresponding to the third data voltage Vdt3 and the gray level corresponding to the fourth data voltage Vdt4. Accordingly, the light of the third light-emitting element LE3 may include both information on the third data voltage Vdt3 and information on the fourth data voltage Vdt4. Accordingly, the loss of image data information in the merged pixels PX3 and PX4 may be reduced or minimized, thereby improving the image quality of the display device 10.

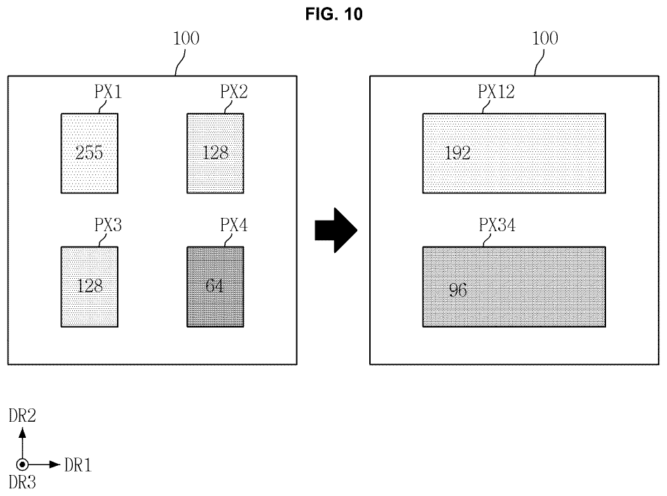

FIG. 10 is a diagram illustrating one or more embodiments of merging of pixels of FIG. 9.

As in the example shown in FIG. 10, when the gray level corresponding to the first data voltage Vdt1 applied to the first pixel PX1 is 255, the gray level corresponding to the second data voltage Vdt2 applied to the second pixel PX2 is 128, and the first pixel PX1 and the second pixel PX2 are connected to each other by the first voltage divider 901 to form one first merged pixel PX12, the light-emitting element (e.g., the first light-emitting element LE1 of the first pixel PX1) of the first merged pixel PX12 may provide light with a luminance corresponding to the first average data voltage corresponding to 192 gray level.

Further, when the gray level corresponding to the third data voltage Vdt3 applied to the third pixel PX3 is 128, the gray level corresponding to the fourth data voltage Vdt4 applied to the fourth pixel PX4 is 64, and the third pixel PX3 and the fourth pixel PX4 are connected to each other by the second voltage divider 902 to form one second merged pixel PX34, the light-emitting element (e.g., the third light-emitting element LE3 of the third pixel PX3) of the second merged pixel PX34 may provide light with a luminance corresponding to the second average data voltage corresponding to 96 gray level.

In accordance with one or more embodiments, the pixel density (e.g., pixel per inch (PPI)) of the display device 10 of FIGS. 9 and 10 may be ½ of a reference pixel density (e.g., a pixel density in the case where each of four adjacent pixels independently includes a light-emitting element).

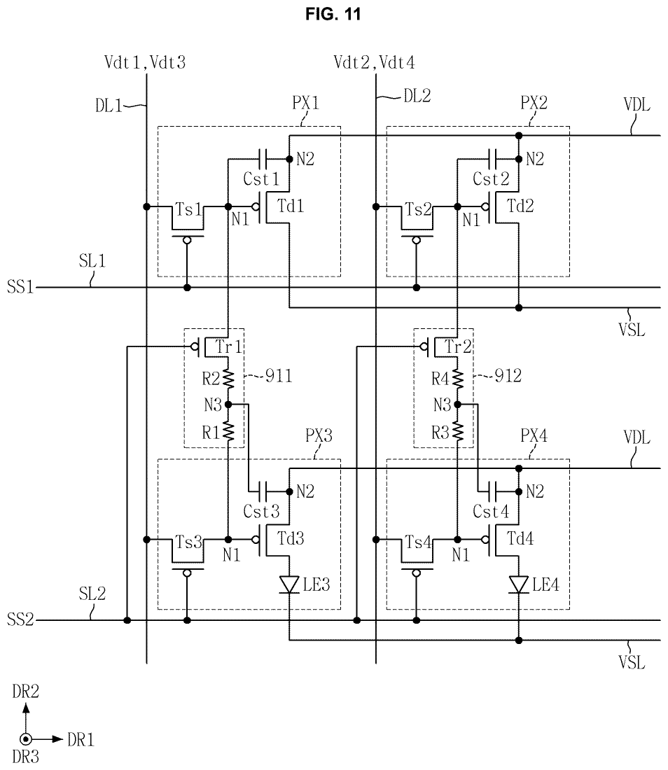

FIG. 11 is an equivalent circuit diagram of a plurality of pixels and a voltage divider of the display device 10 according to one or more embodiments.

As in the example shown in FIG. 11, the display device 10 according to one or more embodiments may include the first pixel PX1, the second pixel PX2, the third pixel PX3, the fourth pixel PX4, a first voltage divider 911, and a second voltage divider 912.

Here, the relative positional relationship of the first pixel PX1, the second pixel PX2, the third pixel PX3, and the fourth pixel PX4 of FIG. 11 may be the same as the relative positional relationship of the first pixel PX1, the second pixel PX2, the third pixel PX3, and the fourth pixel PX4 of FIG. 9 described above.

The first pixel PX1 may include the first switching transistor Ts1, the first driving transistor Td1, and the first capacitor Cst1.

The first switching transistor Ts1 of the first pixel PX1 may include a gate electrode connected to the first scan line SL1, a source electrode connected to the first data line DL1, and a drain electrode connected to the first node N1 (e.g., the gate electrode of the first driving transistor Td1) of the first pixel PX1.

The first driving transistor Td1 of the first pixel PX1 may include a gate electrode connected to the first node N1 (e.g., the drain electrode of the first switching transistor Ts1) of the first pixel PX1, a source electrode connected to the driving voltage line VDL through the second node N2 of the first pixel PX1, and a drain electrode connected to the common voltage line VSL.

The first capacitor Cst1 of the first pixel PX1 may include a first electrode connected to the first node N1 of the first pixel PX1 and a second electrode connected to the second node N2 of the first pixel PX1.

The second pixel PX2 may include the second switching transistor Ts2, a second driving transistor Td2, and a second capacitor Cst2.

The second switching transistor Ts2 of the second pixel PX2 may include a gate electrode connected to the first scan line SL1, a source electrode connected to the second data line DL2, and a drain electrode connected to the first node N1 (e.g., the gate electrode of the second driving transistor Td2) of the second pixel PX2.

The second driving transistor Td2 of the second pixel PX2 may include a gate electrode connected to the first node N1 (e.g., the drain electrode of the second switching transistor Ts2) of the second pixel PX2, a source electrode connected to the driving voltage line VDL through the second node N2 of the second pixel PX2, and a drain electrode connected to the common voltage line VSL.

The second capacitor Cst2 of the second pixel PX2 may include a first electrode connected to the first node N1 of the second pixel PX2 and a second electrode connected to the second node N2 of the second pixel PX2.

The third pixel PX3 may include the third switching transistor Ts3, the third driving transistor Td3, the third capacitor Cst3, and the third light-emitting element LE3.

The third switching transistor Ts3 of the third pixel PX3 may include a gate electrode connected to the second scan line SL2, a source electrode connected to the first data line DL1, and a drain electrode connected to the first node N1 (e.g., the gate electrode of the third driving transistor Td3) of the third pixel PX3.

The third driving transistor Td3 of the third pixel PX3 may include a gate electrode connected to the first node N1 (e.g., the drain electrode of the third switching transistor Ts3) of the third pixel PX3, a source electrode connected to the driving voltage line VDL through the second node N2 of the third pixel PX3, and a drain electrode connected to the anode electrode of the third light-emitting element LE3.

The third capacitor Cst3 of the third pixel PX3 may include a first electrode connected to the first voltage divider 911 and a second electrode connected to the second node N2 (e.g., the source electrode of the third driving transistor Td3) of the third pixel PX3. For example, the first electrode of the third capacitor Cst3 may be connected to the third node N3 (e.g., the junction between the first resistor R1 and the second resistor R2) of the first voltage divider 911.

The third light-emitting element LE3 of the third pixel PX3 may include an anode electrode connected to the drain electrode of the third driving transistor Td3 and a cathode electrode connected to the common voltage line VSL.

The fourth pixel PX4 may include the fourth switching transistor Ts4, a fourth driving transistor Td4, a fourth capacitor Cst4, and a fourth light-emitting element LE4.

The fourth switching transistor Ts4 of the fourth pixel PX4 may include a gate electrode connected to the second scan line SL2, a source electrode connected to the second data line DL2, and a drain electrode connected to the first node N1 (e.g., the gate electrode of the fourth driving transistor Td4) of the fourth pixel PX4.

The fourth driving transistor Td4 of the fourth pixel PX4 may include a gate electrode connected to the first node N1 (e.g., the drain electrode of the fourth switching transistor Ts4) of the fourth pixel PX4, a source electrode connected to the driving voltage line VDL through the second node N2 of the fourth pixel PX4, and a drain electrode connected to the anode electrode of the fourth light-emitting element LE4.

The fourth capacitor Cst4 of the fourth pixel PX4 may include a first electrode connected to the second voltage divider 912 and a second electrode connected to the second node N2 (e.g., the source electrode of the fourth driving transistor Td4) of the fourth pixel PX4. For example, the first electrode of the fourth capacitor Cst4 may be connected to the third node N3 (e.g., the junction between the third resistor R3 and the fourth resistor R4) of the second voltage divider 912.

The fourth light-emitting element LE4 of the fourth pixel PX4 may include an anode electrode connected to the drain electrode of the fourth driving transistor Td4 and a cathode electrode connected to the common voltage line VSL.

The first voltage divider 911 may connect the first pixel PX1 and the third pixel PX3 adjacent in the second direction DR2 in the first column to each other. The first voltage divider 911 may generate a first intermediate data voltage based on the first data voltage Vdt1 applied to the first pixel PX1 and the third data voltage Vdt3 applied to the third pixel PX3. Here, the first data voltage Vdt1 applied to the first pixel PX1 may be, e.g., the first data voltage Vdt1 applied to the first node N1 of the first pixel PX1 through the turned-on first switching transistor Ts1. Further, the third data voltage Vdt3 applied to the third pixel PX3 may be, e.g., the third data voltage Vdt3 applied to the first node N1 of the third pixel PX3 through the turned-on third switching transistor Ts3. The first average data voltage may include an average value for the first data voltage Vdt1 applied to the first pixel PX1 and the third data voltage Vdt3 applied to the third pixel PX3. For example, a value obtained by dividing the sum of the value of the first data voltage Vdt1 applied to the first pixel PX1 and the value of the third data voltage Vdt3 applied to the third pixel PX3 by 2 may be the value of the aforementioned first average data voltage.

The first voltage divider 911 may include at least one resistor and a first transistor Tr1. For example, the first voltage divider 911 may include the first resistor R1 and the second resistor R2 connected to each other through the third node N3 of the first voltage divider 911.

The first resistor R1 of the first voltage divider 911 may be connected between the first node N1 (e.g., the gate electrode of the third driving transistor Td3) of the third pixel PX3 and the third node N3 of the first voltage divider 911.

The second resistor R2 of the first voltage divider 911 may be connected between the third node N3 of the first voltage divider 911 and the drain electrode of the first transistor Tr1 of the first voltage divider 911.

The first transistor Tr1 of the first voltage divider 911 may include a gate electrode connected to the second scan line SL2, a source electrode connected to the first node N1 (e.g., the gate electrode of the first driving transistor Td1) of the first pixel PX1, and a drain electrode connected to the second resistor R2 of the first voltage divider 911.

In one or more embodiments, the number of pixels connected to each other by the first voltage divider 911 may be two or more. For example, three or more pixels adjacent to each other in the second direction DR2 in the first column may be connected to each other by the first voltage divider 911.

The second voltage divider 912 may connect the second pixel PX2 and the fourth pixel PX4 adjacent in the second direction DR2 in the second column to each other. The second voltage divider 912 may generate a second intermediate data voltage based on the second data voltage Vdt2 applied to the second pixel PX2 and the fourth data voltage Vdt4 applied to the fourth pixel PX4. Here, the second data voltage Vdt2 applied to the second pixel PX2 may be, e.g., the second data voltage Vdt2 applied to the first node N1 of the second pixel PX2 through the turned-on second switching transistor Ts2. Further, the fourth data voltage Vdt4 applied to the fourth pixel PX4 may be, e.g., the fourth data voltage Vdt4 applied to the first node N1 of the fourth pixel PX4 through the turned-on fourth switching transistor Ts4. The second average data voltage may include an average value for the second data voltage Vdt2 applied to the second pixel PX2 and the fourth data voltage Vdt4 applied to the fourth pixel PX4. For example, a value obtained by dividing the sum of the value of the second data voltage Vdt2 applied to the second pixel PX2 and the value of the fourth data voltage Vdt4 applied to the fourth pixel PX4 by 2 may be the value of the aforementioned second average data voltage.

The second voltage divider 912 may include at least one resistor and a second transistor Tr2. For example, the second voltage divider 912 may include the third resistor R3 and the fourth resistor R4 connected to each other through the third node N3 of the second voltage divider 912.

The third resistor R3 of the second voltage divider 912 may be connected between the first node N1 (e.g., the gate electrode of the fourth driving transistor Td4) of the fourth pixel PX4 and the third node N3 of the second voltage divider 912.

The fourth resistor R4 of the second voltage divider 912 may be connected between the third node N3 of the second voltage divider 912 and the drain electrode of the second transistor Tr2.

The second transistor Tr2 of the second voltage divider 912 may include a gate electrode connected to the second scan line SL2, a source electrode connected to the first node N1 (e.g., the gate electrode of the second driving transistor Td2) of the second pixel PX2, and a drain electrode connected to the fourth resistor R4 of the second voltage divider 912.

In one or more embodiments, the number of pixels connected to each other by the second voltage divider 912 may be two or more. For example, three or more pixels adjacent to each other in the second direction DR2 in the second column may be connected to each other by the second voltage divider 912.

The operation of the display device 10 of FIG. 11 configured as described above will be described below.

When the first scan signal SS1 is applied to the first scan line SL1, the first switching transistor Ts1 and the second switching transistor Ts2 connected to the first scan line SL1 through the gate electrode may each be turned on.

During a period in which the first scan signal SS1 is applied to the first scan line SL1, the first data voltage Vdt1 may be applied to the first data line DL1, and the second data voltage Vdt2 may be applied to the second data line DL2.

The first data voltage Vdt1 from the first data line DL1 may be applied to the first node N1 (e.g., the gate electrode of the first driving transistor Td1) of the first pixel PX1 through the turned-on first switching transistor Ts1. Further, the second data voltage Vdt2 from the second data line DL2 may be applied to the second pixel PX2 through the turned-on second switching transistor Ts2. For example, the second data voltage Vdt2 may be applied to the first node N1 (e.g., the gate electrode of the second driving transistor Td2) of the second pixel PX2 through the turned-on second switching transistor Ts2.

The first data voltage Vdt1 applied to the first node N1 of the first pixel PX1 and the second data voltage Vdt2 applied to the first node N1 of the second pixel PX2 may be applied to the first voltage divider 911 and the second voltage divider 912, respectively. For example, the first data voltage Vdt1 of the first pixel PX1 may be applied to the source electrode of the first transistor Tr1 provided in the first voltage divider 911, and the second data voltage Vdt2 of the second pixel PX2 may be applied to the source electrode of the second transistor Tr2 provided in the second voltage divider 912. In this case, the first data voltage Vdt1 of the first node N1 of the first pixel PX1 may be stored and maintained in the first capacitor Cst1, and the second data voltage Vdt2 of the first node N1 of the second pixel PX2 may be stored and maintained in the second capacitor Cst2.

Thereafter, when the second scan signal SS2 is applied to the second scan line SL2, the third switching transistor Ts3, the fourth switching transistor Ts4, the first transistor Tr1 of the first voltage divider 911, and the second transistor Tr2 of the second voltage divider 912 that are connected to the second scan line SL2 through their respective gate electrodes may each be turned on.

During the period in which the second scan signal SS2 is applied to the second scan line SL2, the third data voltage Vdt3 may be applied to the first data line DL1, and the fourth data voltage Vdt4 may be applied to the second data line DL2.

The third data voltage Vdt3 from the first data line DL1 may be applied to the first node N1 (e.g., the gate electrode of the third driving transistor Td3) of the third pixel PX3 through the turned-on third switching transistor Ts3. Further, the fourth data voltage Vdt4 from the second data line DL2 may be applied to the first node N1 (e.g., the gate electrode of the fourth driving transistor Td4) of the fourth pixel PX4 through the turned-on fourth switching transistor Ts4.

The third data voltage Vdt3 applied to the first node N1 of the third pixel PX3 and the fourth data voltage Vdt4 applied to the first node N1 (e.g., the drain electrode of the fourth switching transistor Ts4) of the fourth pixel PX4 may be applied to the first voltage divider 911 and the second voltage divider 912, respectively. For example, the third data voltage Vdt3 of the third pixel PX3 may be applied to the first resistor R1 of the first voltage divider 911, and the fourth data voltage Vdt4 of the fourth pixel PX4 may be applied to the third resistor R3 of the second voltage divider 912.

Because the first transistor Tr1 of the first voltage divider 911 is turned on, the first data voltage Vdt1 applied to the first pixel PX1 and the third data voltage Vdt3 applied to the third pixel PX3 may be applied to the third node N3 of the first voltage divider 911. In this case, the first data voltage Vdt1 applied to the first pixel PX1 and the third data voltage Vdt3 applied to the third pixel PX3 may be divided according to the resistance ratio of the first resistor R1 and the second resistor R2 of the first voltage divider 911, and the divided voltage may be the aforementioned first average data voltage. The first average data voltage may be provided through the third node N3 of the first voltage divider 911. For example, the first average data voltage from the first voltage divider 911 may be applied to the first electrode of the third capacitor Cst3. The first average data voltage may be stored and maintained in the third capacitor Cst3.

Because the second transistor Tr2 of the second voltage divider 912 is turned on, the second data voltage Vdt2 applied to the second pixel PX2 and the fourth data voltage Vdt4 applied to the fourth pixel PX4 may be applied to the third node N3 of the second voltage divider 912. In this case, the second data voltage Vdt2 applied to the second pixel PX2 and the fourth data voltage Vdt4 applied to the fourth pixel PX4 may be divided according to the resistance ratio of the third resistor R3 and the fourth resistor R4 of the second voltage divider 912, and the divided voltage may be the aforementioned second average data voltage. The second average data voltage may be provided through the third node N3 of the second voltage divider 912. For example, the second average data voltage from the second voltage divider 912 may be applied to the first electrode of the fourth capacitor Cst4. The second average data voltage may be stored and maintained in the fourth capacitor Cst4.

Therefore, during the emission period of the third pixel PX3 and the fourth pixel PX4, the voltage of the gate electrode of the third driving transistor Td3 may be maintained at the first average data voltage corresponding to the average value of the first data voltage Vdt1 and the third data voltage Vdt3. Further, during the emission period of the third pixel PX3 and the fourth pixel PX4, the voltage of the gate electrode of the fourth driving transistor Td4 may be maintained at the second average data voltage corresponding to the average value of the second data voltage Vdt2 and the fourth data voltage Vdt4.

Therefore, during the emission period of the third pixel PX3 and the fourth pixel PX4, the third driving transistor Td3 may conduct and supply a driving current according to the first average data voltage to the third light-emitting element LE3. During the emission period of the third pixel PX3 and the fourth pixel PX4, the third light-emitting element LE3 may provide light with a luminance of an average gray level corresponding to the average value of the gray level corresponding to the first data voltage Vdt1 and the gray level corresponding to the third data voltage Vdt3. Therefore, the light of the third light-emitting element LE3 may include both information on the first data voltage Vdt1 and information on the third data voltage Vdt3. Accordingly, the loss of image data information in the merged pixels PX1 and PX3 may be reduced or minimized, thereby improving the image quality of the display device 10.

Further, during the emission period of the third pixel PX3 and the fourth pixel PX4, the fourth driving transistor Td4 may conduct and supply a driving current according to the second average data voltage to the fourth light-emitting element LE4. During the emission period of the third pixel PX3 and the fourth pixel PX4, the fourth light-emitting element LE4 may provide light with a luminance of an average gray level corresponding to the average value of the gray level corresponding to the second data voltage Vdt2 and the gray level corresponding to the fourth data voltage Vdt4. Therefore, the light of the fourth light-emitting element LE4 may include both information on the second data voltage Vdt2 and information on the fourth data voltage Vdt4. Accordingly, the loss of image data information in the merged pixels PX2 and PX4 may be reduced or minimized, thereby improving the image quality of the display device 10.

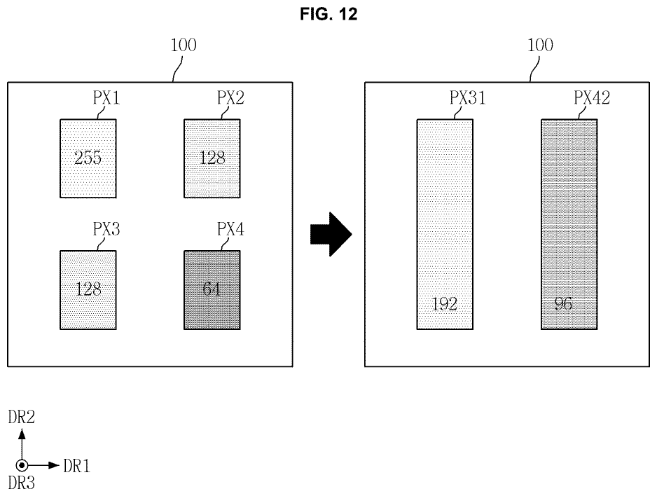

FIG. 12 is a diagram illustrating one or more embodiments of merging of pixels of FIG. 11.

As in the example shown in FIG. 12, when the gray level corresponding to the first data voltage Vdt1 applied to the first pixel PX1 is 255, the gray level corresponding to the third data voltage Vdt3 applied to the third pixel PX3 is 128, and the first pixel PX1 and the third pixel PX3 are connected to each other by the first voltage divider 911 to form one first merged pixel PX31, the light-emitting element (e.g., the third light-emitting element LE3 of the third pixel PX3) of the first merged pixel PX31 may provide light with a luminance corresponding to a data voltage corresponding to 192 gray level.

Further, when the gray level corresponding to the second data voltage Vdt2 applied to the second pixel PX2 is 128, the gray level corresponding to the fourth data voltage Vdt4 applied to the fourth pixel PX4 is 64, and the second pixel PX2 and the fourth pixel PX4 are connected to each other by the second voltage divider 912 to form one second merged pixel PX42, the light-emitting element (e.g., the fourth light-emitting element LE4 of the fourth pixel PX4) of the second merged pixel PX42 may provide light with a luminance corresponding to a data voltage corresponding to 96 gray level.

In accordance with one or more embodiments, the pixel density (e.g., pixel per inch (PPI)) of the display device 10 of FIGS. 11 and 12 may be ½ of a reference pixel density (e.g., a pixel density in the case where each of four adjacent pixels independently includes a light-emitting element).

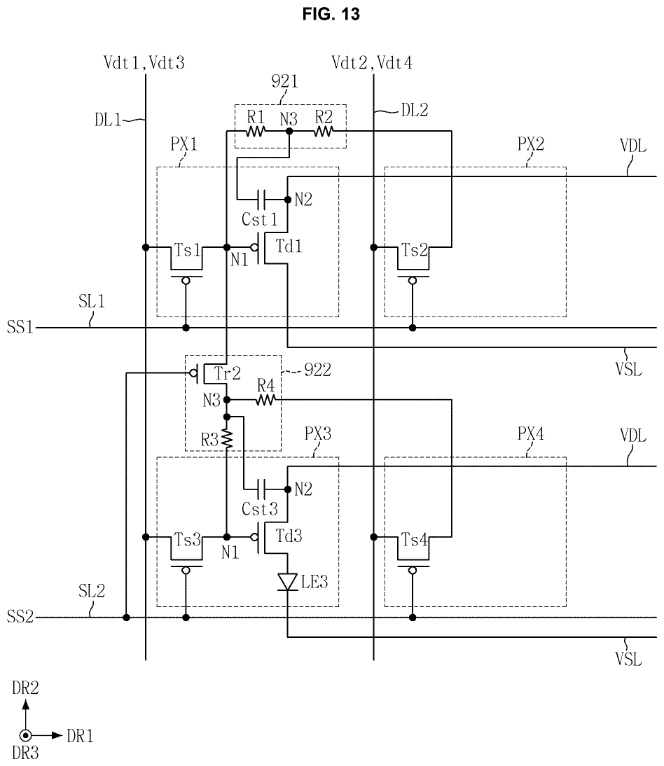

FIG. 13 is an equivalent circuit diagram of a plurality of pixels and a voltage divider of the display device 10 according to one or more embodiments.

As in the example shown in FIG. 13, the display device 10 according to one or more embodiments may include the first pixel PX1, the second pixel PX2, the third pixel PX3, the fourth pixel PX4, a first voltage divider 921, and a second voltage divider 922.

Here, the relative positional relationship of the first pixel PX1, the second pixel PX2, the third pixel PX3, and the fourth pixel PX4 of FIG. 13 may be the same as the relative positional relationship of the first pixel PX1, the second pixel PX2, the third pixel PX3, and the fourth pixel PX4 of FIG. 9 described above.

The first pixel PX1 may include the first switching transistor Ts1, the first driving transistor Td1, and the first capacitor Cst1.

The first switching transistor Ts1 of the first pixel PX1 may include a gate electrode connected to the first scan line SL1, a source electrode connected to the first data line DL1, and a drain electrode connected to the first node N1 (e.g., the gate electrode of the first driving transistor Td1) of the first pixel PX1.

The first driving transistor Td1 of the first pixel PX1 may include a gate electrode connected to the first node N1 (e.g., the drain electrode of the first switching transistor Ts1) of the first pixel PX1, a source electrode connected to the driving voltage line VDL through the second node N2 of the first pixel PX1, and a drain electrode connected to the common voltage line VSL.

The first capacitor Cst1 of the first pixel PX1 may include a first electrode connected to the first voltage divider 921 and a second electrode connected to the second node N2 (e.g., the source electrode of the first driving transistor Td1) of the first pixel PX1. For example, the first electrode of the first capacitor Cst1 may be connected to the third node N3 (e.g., the junction between the first resistor R1 and the second resistor R2) of the first voltage divider 921.

The second pixel PX2 may include the second switching transistor Ts2. The second switching transistor Ts2 may include a gate electrode connected to the first scan line SL1, a source electrode connected to the second data line DL2, and a drain electrode connected to the first voltage divider 921. For example, the drain electrode of the second switching transistor Ts2 may be connected to the second resistor R2 of the first voltage divider 921.

The first voltage divider 921 of FIG. 13 may generate the first average data voltage for the first data voltage Vdt1 applied to the first pixel PX1 and the second data voltage Vdt2 applied to the second pixel PX2. For example, the first voltage divider 921 of FIG. 13 may be the same as the first voltage divider 901 of FIG. 9 described above.

The third pixel PX3 may include a third switching transistor Ts3, a third driving transistor Td3, a third capacitor Cst3, and a third light-emitting element LE3.

The third switching transistor Ts3 of the third pixel PX3 may include a gate electrode connected to the second scan line SL2, a source electrode connected to the first data line DL1, and a drain electrode connected to the first node N1 (e.g., the gate electrode of the third driving transistor Td3) of the third pixel PX3.

The third driving transistor Td3 of the third pixel PX3 may include a gate electrode connected to the first node N1 (e.g., the drain electrode of the third switching transistor Ts3) of the third pixel PX3, a source electrode connected to the driving voltage line VDL through the second node N2 of the third pixel PX3, and a drain electrode connected to the anode electrode of the third light-emitting element LE3.

The third capacitor Cst3 of the third pixel PX3 may include a first electrode connected to the second voltage divider 922 and a second electrode connected to the second node N2 (e.g., the source electrode of the third driving transistor Td3) of the third pixel PX3. For example, the first electrode of the third capacitor Cst3 may be connected to the third node N3 (e.g., the junction between the third resistor R3, the fourth resistor R4, and the second transistor Tr2) of the second voltage divider 922.

The fourth pixel PX4 may include the fourth switching transistor Ts4. The fourth switching transistor Ts4 may include a gate electrode connected to the second scan line SL2, a source electrode connected to the second data line DL2, and a drain electrode connected to the second voltage divider 922. For example, the drain electrode of the fourth switching transistor Ts4 may be connected to the fourth resistor R4 of the second voltage divider 922.

The second voltage divider 922 may connect the first pixel PX1 and the third pixel PX3 adjacent in the second direction DR2 in the first column to each other. The second voltage divider 922 may generate a second intermediate data voltage based on the first data voltage Vdt1 applied to the first pixel PX1 and the third data voltage Vdt3 applied to the third pixel PX3. Here, the first data voltage Vdt1 applied to the first pixel PX1 may be, e.g., the first data voltage Vdt1 applied to the first node N1 of the first pixel PX1 through the turned-on first switching transistor Ts1. Further, the third data voltage Vdt3 applied to the third pixel PX3 may be, e.g., the third data voltage Vdt3 applied to the first node N1 of the third pixel PX3 through the turned-on third switching transistor Ts3. The second average data voltage may include an average value for the first data voltage Vdt1 applied to the first pixel PX1 and the third data voltage Vdt3 applied to the third pixel PX3. For example, a value obtained by dividing the sum of the value of the first data voltage Vdt1 applied to the first pixel PX1 and the value of the third data voltage Vdt3 applied to the third pixel PX3 by 2 may be the value of the aforementioned second average data voltage.

The second voltage divider 922 may include at least one resistor and the second transistor Tr2. For example, the second voltage divider 922 may include the third resistor R3, the fourth resistor R4, and the second transistor Tr2 that are connected to each other through the third node N3 of the second voltage divider 922.

The third resistor R3 of the second voltage divider 922 may be connected between the first node N1 (e.g., the gate electrode of the third driving transistor Td3) of the third pixel PX3 and the third node N3 of the second voltage divider 922.

The fourth resistor R4 of the second voltage divider 922 may be connected between the third node N3 of the second voltage divider 922 and the drain electrode of the fourth switching transistor Ts4 of the fourth pixel PX4.

The second transistor Tr2 of the second voltage divider 922 may include a gate electrode connected to the second scan line SL2, a source electrode connected to the first node N1 (e.g., the gate electrode of the first driving transistor Td1) of the first pixel PX1, and a drain electrode connected to the third node N3 of the second voltage divider 922.

In one or more embodiments, the number of pixels connected to each other by the second voltage divider 922 may be two or more. For example, three or more pixels adjacent to each other in the second direction DR2 in the first column may be connected to each other by the second voltage divider 922.

In accordance with the display device 10 of FIG. 13, the first voltage divider 921 and the second voltage divider 922 may be connected to each other through the first node N1 of the first pixel PX1. Accordingly, the first to fourth pixels PX1 to PX4 may be connected to each other by the first voltage divider 921 and the second voltage divider 922.

Because the operation of the display device 10 of FIG. 13 configured as described above is substantially the same as the operation of the display device 10 of FIG. 9 described above and the operation of the display device 10 of FIG. 11 described above, the operation of the display device of FIG. 13 refers to the operation of the display device 10 of FIGS. 9 and 11.

For example, the operation of the first voltage divider 921 of FIG. 13 refers to the operation of the first voltage divider 901 of FIG. 9 described above, and the operation of the second voltage divider 922 of FIG. 13 refers to the operation of the first voltage divider 911 of FIG. 11 described above. For example, in accordance with the operation of the display device 10 of FIG. 13, when the first scan signal SS1 is applied to the first scan line SL1 to turn on each of the first switching transistor Ts1 and the second switching transistor Ts2, the first average data voltage corresponding to the average value of the first data voltage Vdt1 applied to the first pixel PX1 and the second data voltage Vdt2 applied to the second pixel PX2 may be applied to the third node N3 of the first voltage divider 921. The first average data voltage of the third node N3 of the first voltage divider 921 may be stored and maintained in the first capacitor Cst1.

When the second scan signal SS2 is applied to the second scan line SL2 to turn on each of the third switching transistor Ts3, the fourth switching transistor Ts4, and the second transistor Tr2 of the second voltage divider 922, the second average data voltage corresponding to the average value for the third data voltage Vdt3 applied to the third pixel PX3, the fourth data voltage Vdt4 applied to the fourth node, and the first average data voltage applied to the third node N3 of the first voltage divider 921 may be applied to the third node N3 of the second voltage divider 922. In other words, the average data voltage that is the average value for the first data voltage Vdt1 applied to the first pixel PX1, the second data voltage Vdt2 applied to the second pixel PX2, the third data voltage Vdt3 applied to the third pixel PX3, and the fourth data voltage Vdt4 applied to the fourth pixel PX4 may be applied to the third node N3 of the second voltage divider 922. The average data voltage may be stored and maintained in the third capacitor Cst3 of the third pixel PX3.

The light of the third light-emitting element LE3 may include all information on the first data voltage Vdt1, information on the second data voltage Vdt2, information on the third data voltage Vdt3, and information on the fourth data voltage Vdt4. Accordingly, the loss of image data information in the merged pixels PX1, PX2, PX3, and PX4 may be reduced or minimized, thereby improving the image quality of the display device 10.

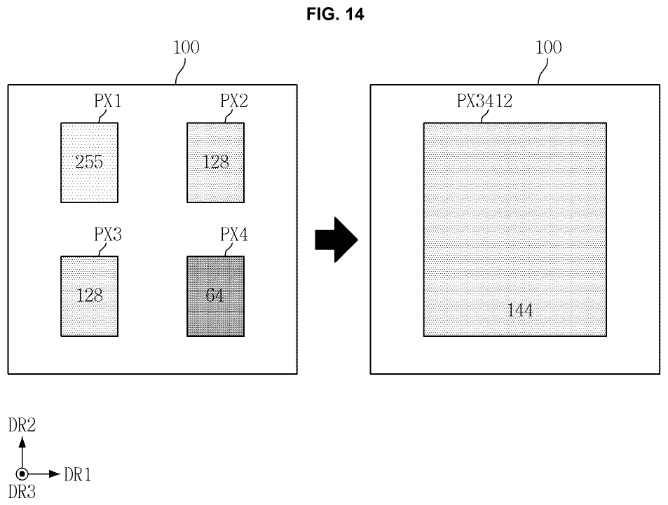

FIG. 14 is a diagram illustrating one or more embodiments of merging of pixels of FIG. 13.

As in the example shown in FIG. 14, when the gray level corresponding to the first data voltage Vdt1 applied to the first pixel PX1 is 255, the gray level corresponding to the second data voltage Vdt2 applied to the second pixel PX2 is 128, the gray level corresponding to the third data voltage Vdt3 applied to the third pixel PX3 is 128, the gray level corresponding to the fourth data voltage Vdt4 applied to the fourth pixel PX4 is 64, and the first to fourth pixels PX1 to PX4 are connected to each other by the first voltage divider 921 and the second voltage divider 922 to form one merged pixel PX3412, the light-emitting element (e.g., the third light-emitting element LE3 of the third pixel PX3) of the merged pixel PX3412 may provide light with a luminance corresponding to an average data voltage corresponding to 144 gray level.

In accordance with one or more embodiments, the pixel density (e.g., pixel per inch (PPI)) of the display device 10 of FIGS. 13 and 14 may be ¼ of a reference pixel density (e.g., a pixel density in the case where each of four adjacent pixels independently includes a light-emitting element).

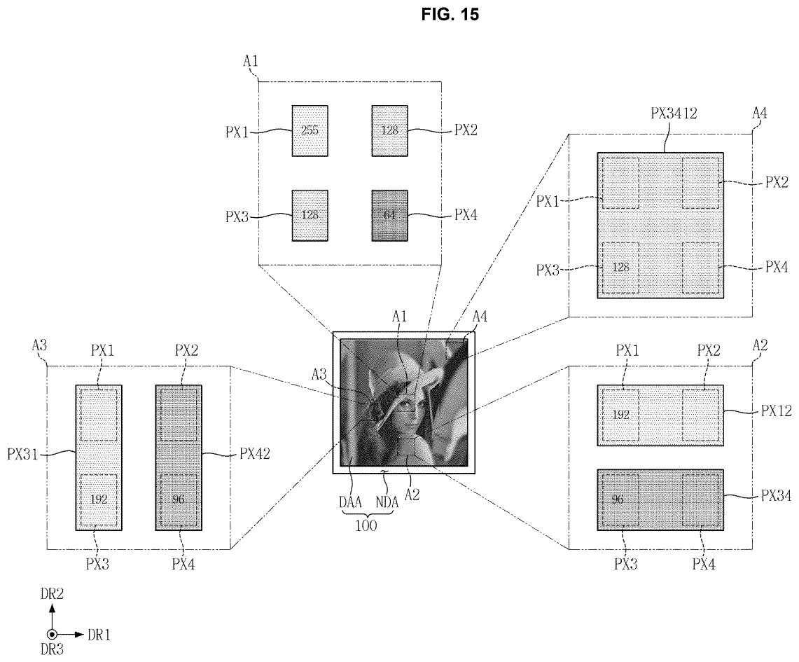

In accordance with the display device 10 of one or more embodiments, the pixel density at the center of the display area where the user's visual field is mainly located may be high, whereas the pixel density at the edge of the display area may be low. This will be described in detail with reference to FIG. 15 below.

FIG. 15 is a diagram illustrating a pixel density for each area of the display device 10 according to one or more embodiments.

As in the example shown in FIG. 15, the display device 10 includes the display panel 100, and the edge of the display panel 100 may have a pixel density lower than that of the center of the display panel 100. For example, the pixel density may decrease from the center toward the edge of the display panel 100. In other words, the display panel 100 may include the display area DAA and the non-display area NDA, and the pixel density may gradually decrease from the center of the display area DAA toward the edge of the display area DAA.

Referring to the example shown in FIG. 15, a first area A1 located at the center of the display area DAA may have the highest pixel density, and a fourth area A4 located at the edge of the display area DAA may have the lowest pixel density. In one or more embodiments, a second area A2 located between the first area A1 and the fourth area A4 in the display area DAA may have a pixel density lower than that of the first area A1 and higher than that of the fourth area A4. The pixel density of a third area A3 may be the same as the pixel density of the second area A2. For example, the pixel density of the second area A2 may be ½ of the pixel density of the first area A1, the pixel density of the third area A3 may be ½ of the pixel density of the first area A1, and the pixel density of the fourth area A4 may be ¼ of the pixel density of the first area A1.

Each of the four pixels PX1, PX2, PX3, and PX4 adjacent to each other in the first direction DR1 and/or the second direction DR2 may be disposed in the first area A1, and the first to fourth pixels PX1 to PX4 of the first area A1 may individually include light-emitting elements. For example, the first pixel PX1 of the first area A1 may include the first light-emitting element LE1, the second pixel PX2 of the first area A1 may include the second light-emitting element LE2, the third pixel PX3 of the first area A1 may include the third light-emitting element LE3, and the fourth pixel PX4 of the first area A1 may include the fourth light-emitting element LE4. For example, each of the first to fourth pixels PX1 to PX4 of the first area A1 may have the same configuration as that of the first pixel PX1 of FIG. 8 described above. Accordingly, the first light-emitting element LE1 of the first pixel PX1 disposed in the first area A1 may provide light with a luminance corresponding to the first data voltage (e.g., the first data voltage Vdt1 corresponding to 255 gray level), the second light-emitting element LE2 disposed in the second pixel PX2 of the first area A1 may provide light with a luminance corresponding to the second data voltage (e.g., the second data voltage Vdt2 corresponding to 128 gray level), the third light-emitting element LE3 of the third pixel PX3 disposed in the first area A1 may provide light with a luminance corresponding to the third data voltage (e.g., the third data voltage Vdt3 corresponding to 128 gray level), and the fourth light-emitting element LE4 of the fourth pixel PX4 disposed in the first area A1 may provide light with a luminance corresponding to the fourth data voltage (e.g., the fourth data voltage Vdt4 corresponding to 64 gray level).

The four pixels adjacent in the first direction DR1 and/or the second direction DR2 may be disposed in the second area A2, and the first to fourth pixels PX1 to PX4 of the second area A2 may have the same configurations as those of the first to fourth pixels PX1 to PX4 of FIG. 9 described above, respectively. The light-emitting element (e.g., the first light-emitting element LE1 of the first pixel PX1) of the first merged pixel PX12 including the first pixel PX1 and the second pixel PX2 may provide light with a luminance corresponding to the average value (e.g., the first average data voltage corresponding to 192 gray level) of the first data voltage Vdt1 and the second data voltage Vdt2, and the light-emitting element (e.g., the third light-emitting element LE3 of the third pixel PX3) of the second merged pixel PX34 including the third pixel PX3 and the fourth pixel PX4 may provide light with a luminance corresponding to the average value (e.g., the second average data voltage corresponding to 96 gray level) of the third data voltage Vdt3 and the fourth data voltage Vdt4.

The four pixels PX1 to PX4 adjacent to each other in the first direction DR1 and/or the second direction DR2 may be disposed in the third area A3, and the first to fourth pixels PX1 to PX4 of the third area A3 may have the same configurations as those of the first to fourth pixels PX1 to PX4 of FIG. 11 described above, respectively. The light-emitting element (e.g., the third light-emitting element LE3 of the third pixel PX3) of the first merged pixel PX31 including the first pixel PX1 and the third pixel PX3 may provide light with a luminance corresponding to the average value (e.g., the first average data voltage corresponding to 192 gray level) of the first data voltage Vdt1 and the third data voltage Vdt3, and the light-emitting element (e.g., the fourth light-emitting element LE4 of the fourth pixel PX4) of the second merged pixel PX42 including the second pixel PX2 and the fourth pixel PX4 may provide light with a luminance corresponding to the average value (e.g., the second average data voltage corresponding to 96 gray level) of the second data voltage Vdt2 and the fourth data voltage Vdt4.

The four pixels PX1 to PX4 adjacent to each other in the first direction DR1 and/or the second direction DR2 may be disposed in the fourth area A4, and the first to fourth pixels PX1 to PX4 of the fourth area A4 may have the same configurations as those of the first to fourth pixels PX1 to PX4 of FIG. 13 described above, respectively. The light-emitting element (e.g., the third light-emitting element LE3 of the third pixel PX3) of the merged pixel PX3412 including the first pixel PX1, the second pixel PX2, the third pixel PX3, and the fourth pixel PX4 may provide light with a luminance corresponding to the average value (e.g., an average data voltage corresponding to 144 gray levels) of the first data voltage Vdt1, the second data voltage Vdt2, the third data voltage Vdt3, and the fourth data voltage Vdt4.

In accordance with one or more embodiments, a larger number of pixels may be connected to a voltage divider toward the edge of the display area DAA. For example, in the second area A2, two pixels PX1 and PX2 or PX3 and PX4 adjacent to each other in the first direction DR1 may be connected to each other by the voltage divider, and in the fourth area A4 closer to the edge of the display area DAA than the second area A2, four pixels PX1 to PX4 adjacent to each other in the first direction DR1 and/or the second direction DR2 may be connected to each other by the voltage divider.

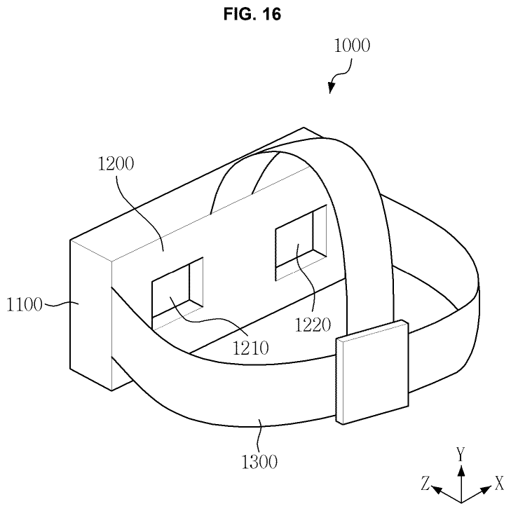

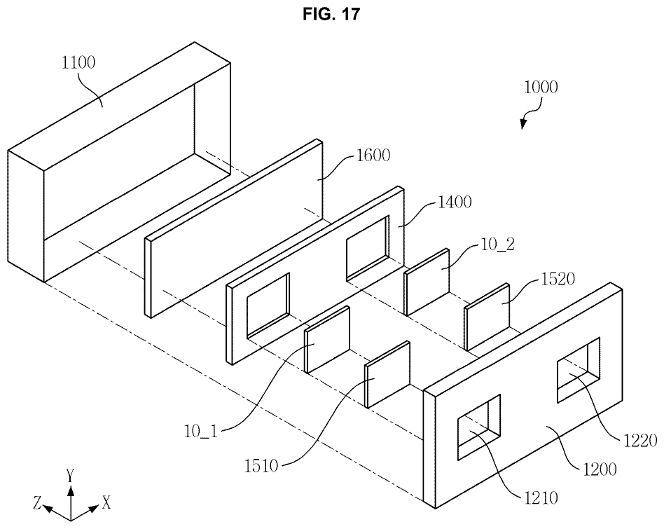

FIG. 16 is a perspective view illustrating a head mounted display according to one or more embodiments. FIG. 17 is an exploded perspective view illustrating an example of the head mounted display of FIG. 16.

Referring to FIGS. 16 and 17, a head mounted display 1000 according to one or more embodiments includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Because each of the first display device 10_1 and the second display device 10_2 is substantially the same as the display device 10 described in conjunction with FIGS. 1-15, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. FIGS. 16 and 17 illustrate that the first eyepiece 1210 and the second eyepiece 1220 are disposed separately, but the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

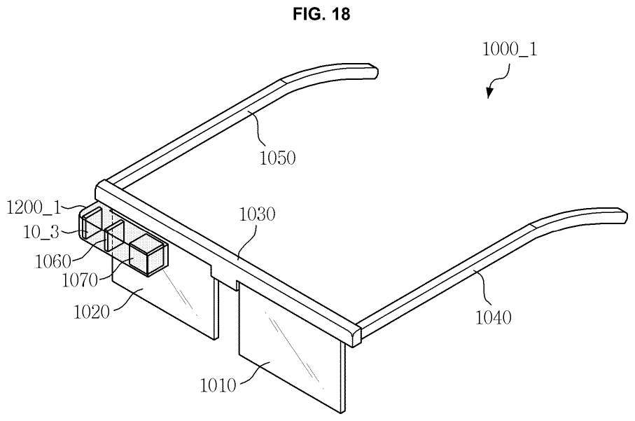

The head mounted band 1300 serves to secure the display device housing 1100 to the user's head such that the first eyepiece 1210 and the second eyepiece 1220 of the housing cover 1200 remain located on the user's left and right eyes, respectively. When the display device housing 1200 is implemented to be lightweight and compact, the head mounted display 1000 may be provided with, as shown in FIG. 18, an eyeglass frame instead of the head mounted band 1300.

In addition, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and/or the wireless communication module may be a 5G communication module, a 4G communication module, a Wi-Fi module, and/or a Bluetooth module.

FIG. 18 is a perspective view illustrating a head mounted display according to one or more embodiment.

Referring to FIG. 18, a head mounted display 1000_1 according to one or more embodiments may be an eyeglasses-type display device in which a display device housing 1200_1 is implemented in a lightweight and compact manner. The head mounted display 1000_1 according to one or more embodiments may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 18 illustrates that the display device housing 1200_1 is disposed at the right end of the support frame 1030, but the present disclosure is not limited thereto. For example, the display device housing 1200_1 may be disposed at the left end of the support frame 1030, and in this case, the image of the display device 10_3 may be provided to the user's left eye. Alternatively, the display device housing 1200_1 may be disposed at both the left and right ends of the support frame 1030, and in this case, the user may view the image displayed on the display device 10_3 through both the left and right eyes.

The display device according to the embodiment can be applied to various electronic devices. The electronic device according to one embodiment includes the display device described above and may further include modules or devices having additional functions in addition to the display device.

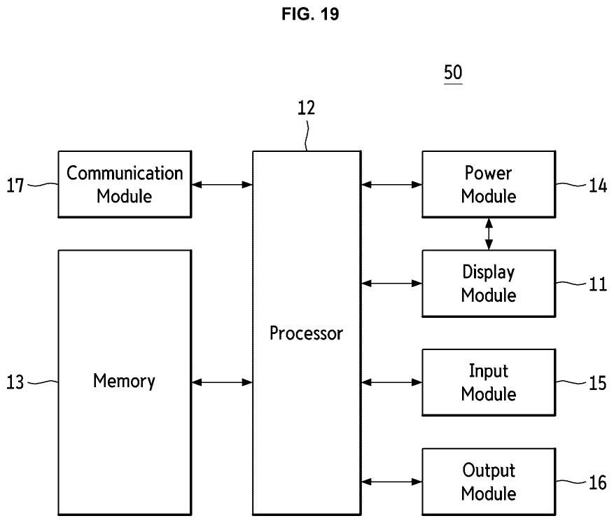

FIG. 19 is a block diagram of an electronic device according to one embodiment. Referring to FIG. 19, the electronic device 50 according to one embodiment may include a display module, a processor 12, a memory 13, and a power module 14. The electronic device 50 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 11. The power module 14 may include a power supply module such as a power adapter or a battery device, and a power conversion module that converts the power supplied by the power supply module to generate power required for the operation of the electronic device 50. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

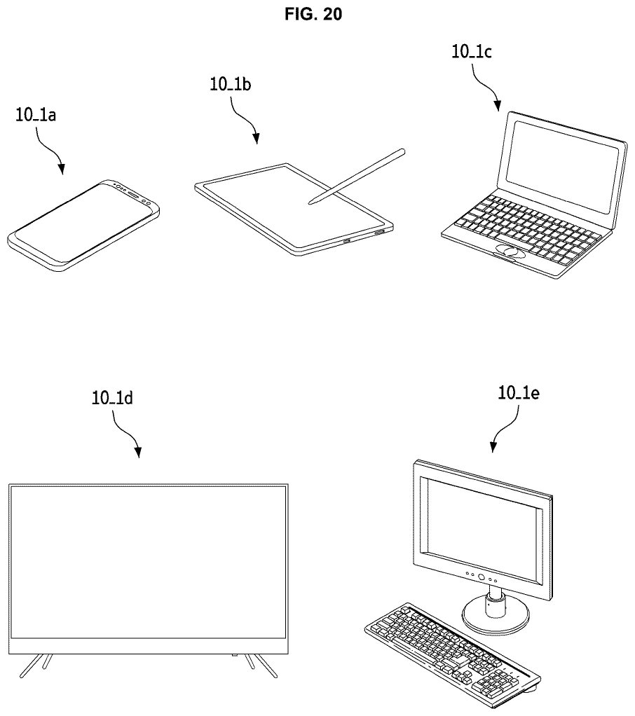

FIGS. 20, 21, and 22 are schematic diagrams of electronic devices according to various embodiments. FIGS. 20 to 22 illustrate examples of various electronic devices to which the display device according to the embodiments is applied.

FIG. 20 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

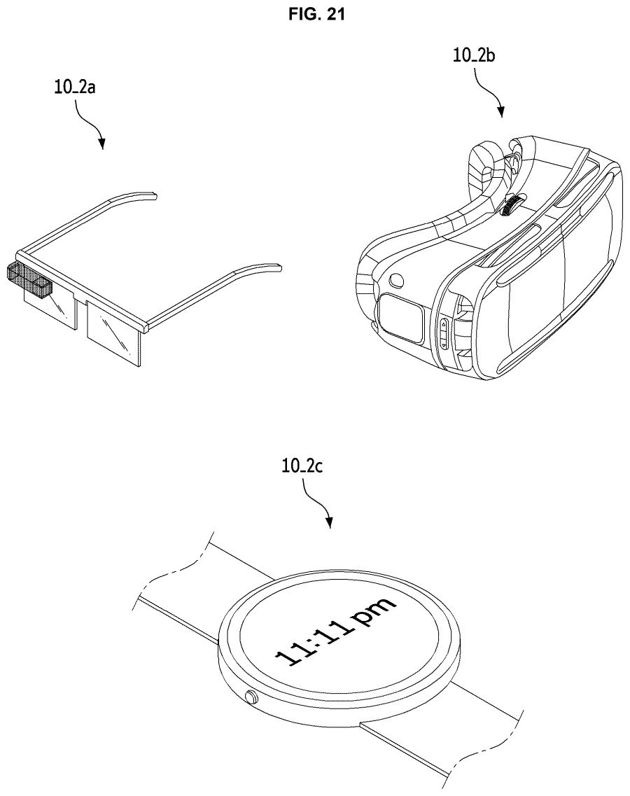

FIG. 21 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

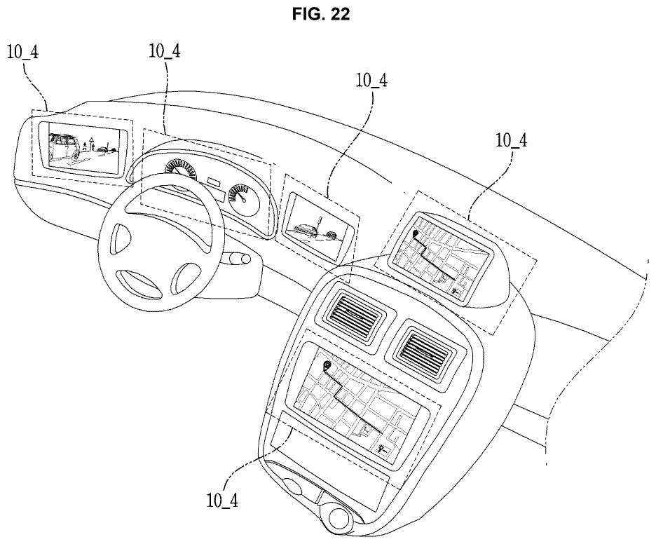

The smart watch 10_2c includes a biometric sensor as an input device, and may provide biometric information recognized by the biometric sensor to the user through the display module. FIG. 22 illustrates a case where an electronic device including a display module is applied to a vehicle. For example, the electronic device 10_4 may be applied to a dashboard, center fascia, etc. of a vehicle, or may be applied to a CID (Center Information Display) placed on a dashboard of a vehicle, or a room mirror display replacing a side mirror.

It will be able to be understood by one of ordinary skill in the art to which the present disclosure belongs that the present disclosure may be implemented in other specific forms without changing the technical spirit or essential features of the present disclosure. Therefore, it is to be understood that the example embodiments described above are illustrative rather than being restrictive in all aspects. It is to be understood that the scope of the present disclosure are defined by the claims and their equivalents rather than the detailed description described above and all modifications and alterations derived from the claims and their equivalents fall within the scope of the present disclosure.

What is claimed is:

1. A display device comprising:
a light-emitting element;
a first switching transistor connected to a scan line and a first data line;
a driving transistor connected to the first switching transistor, a driving voltage line, and the light-emitting element;
a capacitor, one electrode of the capacitor being connected to a source electrode of the driving transistor;
a second switching transistor connected to the scan line and a second data line; and
a voltage divider connected to an other electrode of the capacitor, the first switching transistor, and the second switching transistor.

2. The display device of claim 1, wherein the voltage divider comprises:
a first resistor, one end of the first resistor being connected to a drain electrode of the first switching transistor; and
a second resistor, one end of the second resistor being connected to an other end of the first resistor and the other electrode of the capacitor, and an other end of the second resistor being connected to a drain electrode of the second switching transistor.

3. The display device of claim 1, wherein:
a gate electrode of the first switching transistor is connected to the scan line;
a source electrode of the first switching transistor is connected to the first data line; and
a drain electrode of the first switching transistor is connected to a gate electrode of the driving transistor and the voltage divider.

4. The display device of claim 1, wherein:
a gate electrode of the driving transistor is connected to a drain electrode of the first switching transistor;
the source electrode of the driving transistor is connected to the one electrode of the capacitor and the driving voltage line; and
a drain electrode of the driving transistor is connected to an anode electrode of the light-emitting element.

5. The display device of claim 1, wherein:
a gate electrode of the second switching transistor is connected to the scan line;
a source electrode of the second switching transistor is connected to the second data line; and
a drain electrode of the second switching transistor is connected to the voltage divider.

6. The display device of claim 1, wherein the light-emitting element is at an edge of a display panel of the display device.

7. A display device comprising:
a light-emitting element;
a first switching transistor connected to a first scan line and a data line;
a first driving transistor connected to the first switching transistor, a driving voltage line, and a common voltage line;
a first capacitor, one electrode of the first capacitor being connected to a source electrode of the first driving transistor;
a second switching transistor connected to a second scan line and the data line;
a second driving transistor connected to the second switching transistor, the driving voltage line, and the light-emitting element;
a second capacitor, one electrode of the second capacitor being connected to a source electrode of the second driving transistor; and
a voltage divider connected to an other electrode of the second capacitor, the second scan line, the first switching transistor, and the second switching transistor.

8. The display device of claim 7, wherein the voltage divider comprises:
a first resistor, one end of the first resistor being connected to a drain electrode of the second switching transistor;
a second resistor, one end of the second resistor being connected to an other end of the first resistor and the other electrode of the second capacitor; and
a transistor connected to the second scan line, a drain electrode of the first switching transistor, and an other end of the second resistor.

9. The display device of claim 8, wherein a gate electrode of the transistor is connected to the second scan line,
wherein a source electrode of the transistor is connected to the drain electrode of the first switching transistor, and
wherein a drain electrode of the transistor is connected to the other end of the second resistor.

10. The display device of claim 7, wherein a gate electrode of the first switching transistor is connected to the first scan line,
wherein a source electrode of the first switching transistor is connected to the data line, and
wherein a drain electrode of the first switching transistor is connected to a gate electrode of the first driving transistor, an other electrode of the first capacitor, and the voltage divider.

11. The display device of claim 7, wherein a gate electrode of the first driving transistor is connected to a drain electrode of the first switching transistor,
wherein the source electrode of the first driving transistor is connected to the one electrode of the first capacitor and the driving voltage line, and
wherein a drain electrode of the first driving transistor is connected to the common voltage line.

12. The display device of claim 7, wherein a gate electrode of the second switching transistor is connected to the second scan line,
wherein a source electrode of the second switching transistor is connected to the data line, and
wherein a drain electrode of the second switching transistor is connected to a gate electrode of the second driving transistor and the voltage divider.

13. The display device of claim 7, wherein a gate electrode of the second driving transistor is connected to a drain electrode of the second switching transistor,
wherein the source electrode of the second driving transistor is connected to the one electrode of the second capacitor and the driving voltage line, and
wherein a drain electrode of the second driving transistor is connected to the light-emitting element.

14. The display device of claim 7, wherein the light-emitting element is at an edge of a display panel of the display device.

15. An electronic device comprising:
a display device including a screen,
wherein the display device comprises,
a light-emitting element;
a first switching transistor connected to a scan line and a first data line;
a driving transistor connected to the first switching transistor, a driving voltage line, and the light-emitting element;
a capacitor, one electrode of the capacitor being connected to a source electrode of the driving transistor;
a second switching transistor connected to the scan line and a second data line; and
a voltage divider connected to an other electrode of the capacitor, the first switching transistor, and the second switching transistor.

16. The electronic device of claim 15, wherein the voltage divider comprises:
a first resistor, one end of the first resistor being connected to a drain electrode of the first switching transistor; and
a second resistor, one end of the second resistor being connected to an other end of the first resistor and the other electrode of the capacitor, and an other end of the second resistor being connected to a drain electrode of the second switching transistor.

17. The electronic device of claim 15, wherein:
a gate electrode of the first switching transistor is connected to the scan line;
a source electrode of the first switching transistor is connected to the first data line; and
a drain electrode of the first switching transistor is connected to a gate electrode of the driving transistor and the voltage divider.

18. The electronic device of claim 15, wherein:
a gate electrode of the driving transistor is connected to a drain electrode of the first switching transistor;
the source electrode of the driving transistor is connected to the one electrode of the capacitor and the driving voltage line; and
a drain electrode of the driving transistor is connected to an anode electrode of the light-emitting element.

19. The electronic device of claim 15, wherein:
a gate electrode of the second switching transistor is connected to the scan line;
a source electrode of the second switching transistor is connected to the second data line; and
a drain electrode of the second switching transistor is connected to the voltage divider.

20. The electronic device of claim 15, wherein the light-emitting element is at an edge of a display panel of the display device.
